(19) United States
(12) Patent Application Publication
(10) Pub. No.: US 2026/0182118 A1
(43) Pub. Date: Jun. 25, 2026

(54) DISPLAY APPARATUS AND ELECTRONIC DEVICE INCLUDING THE SAME

(71) Applicant: Samsung Display Co., Ltd., Yongin-si (KR)

(72) Inventors: Jonghwa Park, Yongin-si (KR); Kyungho Kim, Yongin-si (KR); Youngseok Seo, Yongin-si (KR)

(21) Appl. No.: 19/408,119

(22) Filed: Dec. 3, 2025

(30) Foreign Application Priority Data
Dec. 19, 2024 (KR) 10-2024-0191729

(51) Int. Cl. H10H 29/49; H10H 29/32

(52) U.S. Cl. CPC H10H 29/49; H10H 29/32

(57) ABSTRACT

A display apparatus includes: a plurality of first island portions and a plurality of first bridge portions connecting the plurality of first island portions; a pixel circuit layer in each of the plurality of first island portions and comprising an inorganic insulating layer and a pixel driving circuit unit; a light-emitting element on the pixel circuit layer and electrically connected to the pixel driving circuit unit; a first layer comprising a first layer portion on the pixel circuit layer and a first layer opening passing through the first layer portion; a connection wiring in each of the plurality of first bridge portions and having at least a part accommodated in the first layer opening; and a contact wiring electrically connecting the pixel driving circuit unit to the connection wiring.

### CROSS-REFERENCE TO RELATED APPLICATION

The present application claims priority to and the benefit of Korean Patent Application No. 10-2024-0191729, filed on December 19, 2024, in the Korean Intellectual Property Office, the entire disclosure of which is incorporated herein by reference.

### BACKGROUND

### 1. Field

Aspects of some embodiments of the present disclosure relate to a display apparatus and an electronic device including the same.

### 2. Description of the Related Art

As display apparatuses that visually display electrical signals have been developed, various display apparatuses having excellent characteristics such as a thin design, light weight, and low power consumption have been introduced. For example, flexible display apparatuses that may be folded or rolled up have been introduced. Recently, research and development on display apparatuses having various structures, such as stretchable display apparatuses that may be changed into various forms, have been actively conducted.

The above information disclosed in this Background section is only for enhancement of understanding of the background and therefore the information discussed in this Background section does not necessarily constitute prior art.

### SUMMARY

Aspects of some embodiments of the present disclosure relate to a display apparatus and an electronic device including the same, for example, a flexible display apparatus.

Embodiments of the present disclosure provide a display apparatus, for example, a flexible display apparatus.

According to some embodiments of the present disclosure, a display apparatus includes a plurality of first island portions and a plurality of first bridge portions connecting the plurality of first island portions, a pixel circuit layer in each of the plurality of first island portions and including an inorganic insulating layer and a pixel driving circuit unit, a light-emitting element on the pixel circuit layer to be electrically connected to the pixel driving circuit unit, a first layer including a first layer portion on the pixel circuit layer and a first layer opening passing through the first layer portion, a connection wiring in each of the plurality of first bridge portions and having at least a part accommodated in the first layer opening, and a contact wiring electrically connecting the pixel driving circuit unit to the connection wiring.

According to some embodiments, the pixel circuit layer may be between the light-emitting element and the first layer.

According to some embodiments, one side of the contact wiring may contact the connection wiring, and the other side of the contact wiring may be on the inorganic insulating layer and is electrically connected to the pixel driving circuit unit.

According to some embodiments, one side of the contact wiring may contact the connection wiring accommodated in the first layer opening.

According to some embodiments, in a plan view, the first layer may overlap any one of the plurality of first island portions and any one of the plurality of first bridge portions.

According to some embodiments, in a plan view, the first layer may be spaced apart from the plurality of first island portions.

According to some embodiments, a thickness of the connection wiring may be greater than a thickness of the first layer.

According to some embodiments, in a plan view, a shape of the first layer opening may be an elliptical shape.

According to some embodiments, a plurality of first layer openings may be provided.

According to some embodiments, the plurality of first layer openings may be arranged along a circumference of the first layer portion.

According to some embodiments of the present disclosure, an electronic device includes a display apparatus that is stretchable, wherein the display apparatus includes a pixel circuit layer having a first pixel surface and including an inorganic insulating layer and a pixel driving circuit unit, a light-emitting element on the pixel circuit layer to be electrically connected to the pixel driving circuit unit, a first layer including a first layer portion on the first pixel surface and a first layer opening passing through the first layer portion, a connection wiring on the first pixel surface so that at least a part of the connection wiring is accommodated in the first layer opening, and a contact wiring electrically connecting the pixel driving circuit unit to the connection wiring.

According to some embodiments, one side of the contact wiring may be on the first pixel surface and contacts the connection wiring, and the other side of the contact wiring is on the inorganic insulating layer and may be electrically connected to the pixel driving circuit unit.

According to some embodiments, one side of the contact wiring may contact the connection wiring accommodated in the first layer opening.

According to some embodiments, the first pixel surface may be a surface of the pixel circuit layer facing a direction away from the light-emitting element.

According to some embodiments, a thickness of the connection wiring may be greater than a thickness of the first layer.

According to some embodiments, in a plan view, the first layer may overlap the inorganic insulating layer.

According to some embodiments, in a plan view, the first layer may be spaced apart from the inorganic insulating layer.

According to some embodiments, in a plan view, a shape of the first layer opening may be an elliptical shape.

According to some embodiments, a plurality of first layer openings may be provided.

According to some embodiments, the plurality of first layer openings may be arranged along a circumference of the first layer portion.

According to some embodiments of the present disclosure, a display apparatus that is stretchable and has relatively improved durability may be provided. These characteristics are examples and do not limit the scope of embodiments according to the present disclosure.

### BRIEF DESCRIPTION OF THE DRAWINGS

FIG. 1 is a perspective view schematically illustrating a display apparatus, according to some embodiments of the present disclosure.

FIGS. 2A and 2B are perspective views illustrating a state where the display apparatus of FIG. 1 is stretched in a first direction.

FIG. 2C is a perspective view illustrating a state where the display apparatus of FIG. 1 is stretched in a second direction.

FIG. 2D is a perspective view illustrating a state where the display apparatus of FIG. 1 is stretched in the first direction and the second direction.

FIG. 2E is a perspective view illustrating a state where the display apparatus of FIG. 1 is stretched in a third direction.

FIG. 3 is a plan view schematically illustrating a display apparatus, according to some embodiments of the present disclosure.

FIG. 4A is an enlarged plan view illustrating a portion IV of the display apparatus of FIG. 3, according to some embodiments of the present disclosure.

FIG. 4B is an enlarged plan view illustrating the portion IV of the display apparatus of FIG. 3, according to some embodiments of the present disclosure.

FIG. 4C is an enlarged plan view illustrating the portion IV of the display apparatus of FIG. 3, according to some embodiments of the present disclosure.

FIG. 4D is an enlarged plan view illustrating a part of the display apparatus, that is, a display area of FIG. 3, according to some embodiments of the present disclosure.

FIG. 4E is an enlarged plan view illustrating the portion IV of the display apparatus of FIG. 3, according to some embodiments of the present disclosure.

FIG. 5 is a cross-sectional view schematically illustrating a first island portion and a first bridge portion located in a display area of a display apparatus, according to some embodiments of the present disclosure.

FIGS. 6A to 6C are equivalent circuit diagrams illustrating a sub-pixel of a display apparatus, according to some embodiments of the present disclosure.

FIG. 7A is a cross-sectional view schematically illustrating a light-emitting element of a display apparatus, according to some embodiments of the present disclosure.

FIG. 7B is a cross-sectional view schematically illustrating a light-emitting element of a display apparatus, according to some embodiments of the present disclosure.

FIG. 8 is a cross-sectional view schematically illustrating a part of a display apparatus, according to some embodiments of the present disclosure.

FIG. 9 is a plan view schematically illustrating a part of a display apparatus, according to some embodiments of the present disclosure.

FIGS. 10A and 10B are plan views schematically illustrating a first layer, according to some embodiments of the present disclosure.

FIG. 11 is a plan view schematically illustrating a first layer, according to some embodiments of the present disclosure.

FIGS. 12A and 12B are plan views schematically illustrating a first layer, according to some embodiments of the present disclosure.

FIG. 13 is a cross-sectional view schematically illustrating a part of a display apparatus, according to some embodiments of the present disclosure.

FIG. 14 is a plan view schematically illustrating a part of a display apparatus, according to some embodiments of the present disclosure.

FIG. 15A is a perspective view schematically illustrating an electronic device including a display apparatus, according to some embodiments of the present disclosure.

FIG. 15B is a block diagram schematically illustrating an electronic device including a display apparatus, according to some embodiments of the present disclosure.

FIGS. 16A to 16I are perspective views schematically illustrating embodiments of an electronic device including a display apparatus, according to some embodiments of the present disclosure.

### DETAILED DESCRIPTION

As the present disclosure allows for various changes and numerous embodiments, certain embodiments will be illustrated in the drawings and described in the detailed description. Effects and features of the present disclosure, and methods for achieving them will be clarified with reference to embodiments described below in detail with reference to the drawings. However, embodiments according to the present disclosure are not limited to the following embodiments and may be embodied in various forms.

Hereinafter, embodiments of the present disclosure will be described in detail with reference to the accompanying drawings, wherein the same or corresponding elements are denoted by the same reference numerals throughout and a repeated description thereof is omitted.

Although the terms "first," "second," etc. may be used to describe various elements, these elements should not be limited by these terms. These terms are only used to distinguish one element from another.

As used herein, the singular forms "a," "an," and "the" are intended to include the plural forms as well, unless the context clearly indicates otherwise.

It will be understood that the terms "including" and "having" are intended to indicate the existence of the features or elements described in the specification, and are not intended to preclude the possibility that one or more other features or elements may exist or may be added.

It will be further understood that, when a layer, region, or component is referred to as being "on" another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, embodiments according to the present disclosure are not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When a certain embodiment may be implemented differently, a specific process order may be different from the described order. For example, two consecutively described processes may be performed at the same time (or substantially at the same time) or may be performed in an order opposite to the described order.

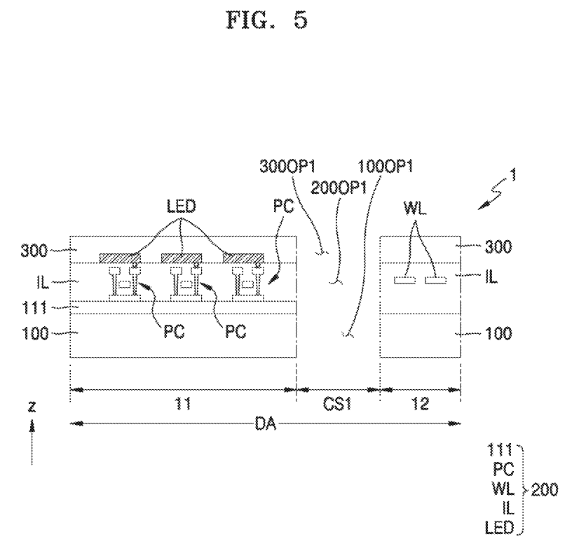

In the specification, a “plan view” refers to a two-dimensional view seen in a direction perpendicular to a substrate 100 (see FIG. 5). That is, “A and B spaced apart from each other in a plan view” means “A and B spaced apart from each other when viewed in a direction perpendicular to the substrate 100 (see FIG. 5).”

In the specification, a “cross-sectional view” refers to a two-dimensional view cut in a direction perpendicular to the substrate 100 (see FIG. 5). That is, “A and B spaced apart from each other in a cross-sectional view” means “A and B spaced apart from each other in a two-dimensional view cut in a direction perpendicular to the substrate 100 (see FIG. 5).”

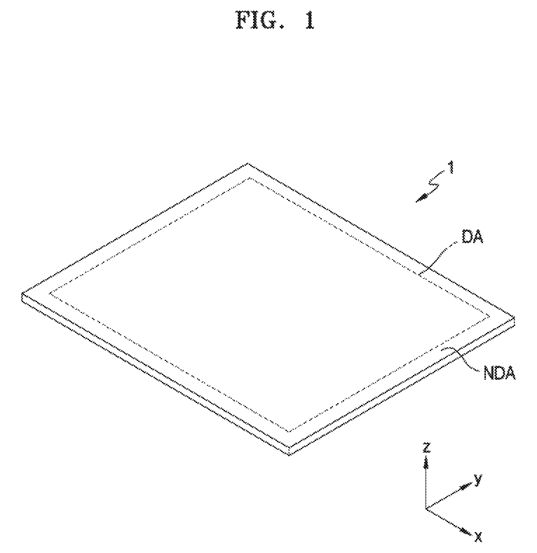

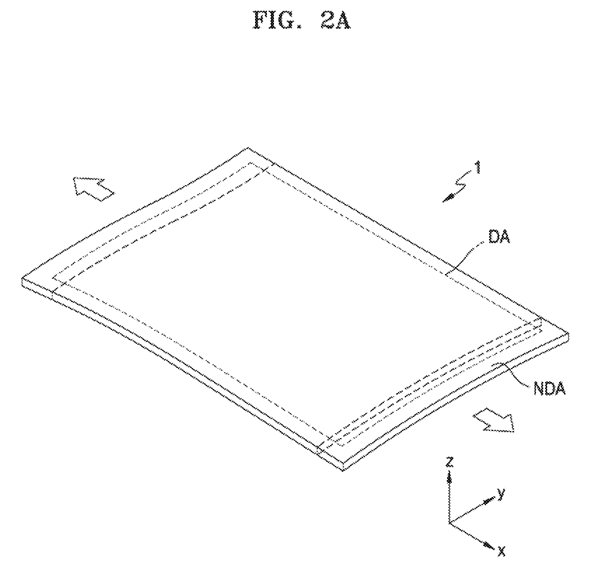

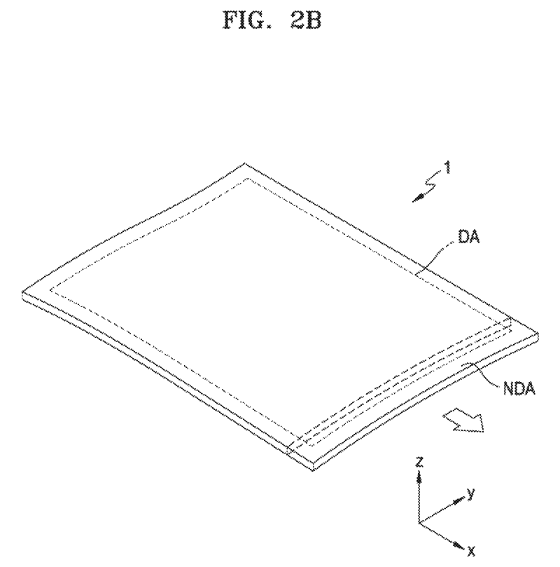

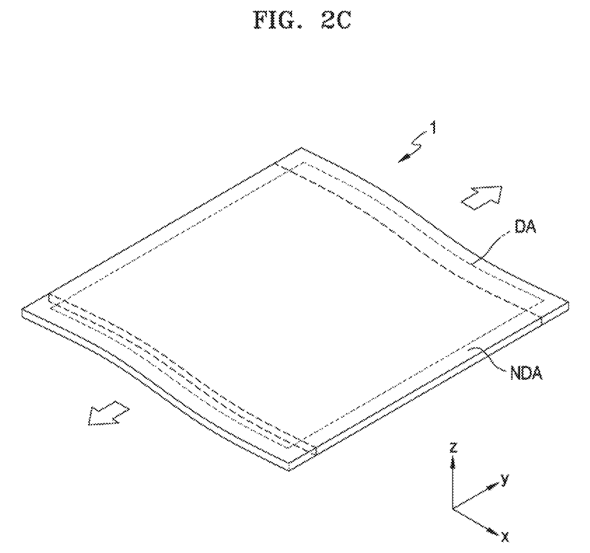

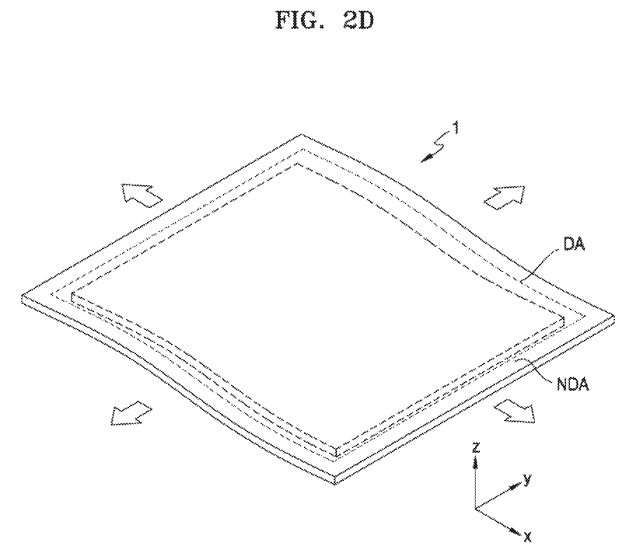

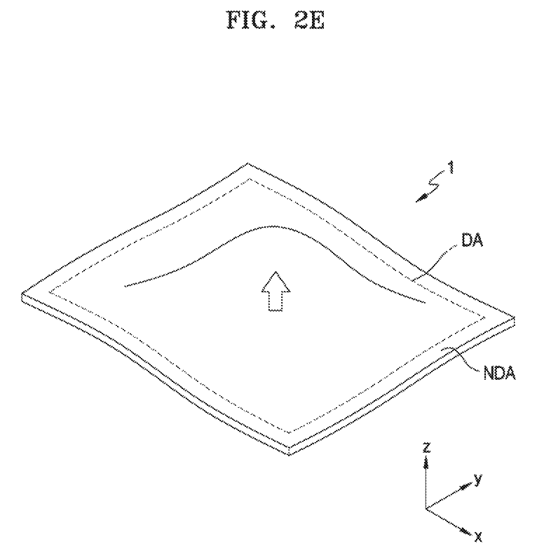

FIG. 1 is a perspective view schematically illustrating a display apparatus 1, according to some embodiments of the present disclosure. FIGS. 2A and 2B are perspective views illustrating a state where the display apparatus 1 of FIG. 1 is stretched in a first direction. FIG. 2C is a perspective view illustrating a state where the display apparatus 1 of FIG. 1 is stretched in a second direction. FIG. 2D is a perspective view illustrating a state where the display apparatus of FIG. 1 is stretched in the first direction and the second direction. FIG. 2E is a perspective view illustrating a state where the display apparatus 1 of FIG. 1 is stretched in a third direction.

Referring to FIG. 1, the display apparatus 1 may include a display area DA and a non-display area NDA. The display area DA may include a plurality of pixels. The display apparatus 1 may display images by using light emitted from the plurality of pixels. The non-display area NDA may be located outside (e.g., in a periphery or outside a footprint of) the display area DA. The non-display area NDA where pixels are not located may entirely surround the display area DA.

The display apparatus 1 may be stretched or shrunk in various directions. The display apparatus 1 may be stretched in the first direction (e.g., an x direction and/or a -x direction) by an external force applied by a user or an external object. According to some embodiments, as shown in FIGS. 2A and 2B, the display area DA and/or the non-display area NDA of the display apparatus 1 may be stretched in the first direction (e.g., the x direction and/or the -x direction). For example, the display area DA and/or the non-display area NDA of the display apparatus 1 may be stretched along the x direction and the -x direction as shown in FIG. 2A, or may be stretched along the x direction with one side fixed as shown in FIG. 2B.

The display apparatus 1 may be stretched in the second direction (e.g., a y direction and/or a -y direction) by an external force applied by a user or an external object. According to some embodiments, the display area DA and/or the non-display area NDA of the display apparatus 1 may be stretched in the y direction and the -y direction as shown in FIG. 2C. According to some embodiments, the display area DA and/or the non-display area NDA of the display apparatus 1 may be stretched in the y direction or the -y direction with one side fixed.

The display apparatus 1 may be stretched in a plurality of directions, for example, in the first direction (e.g., the x direction and/or the -x direction) and the second direction (e.g., the y direction and/or the -y direction) by an external force applied by a person’s body part or an external object. The display area DA and/or the non-display area NDA of the display apparatus 1 may be stretched in the ±x direction and the ±y direction as shown in FIG. 2D.

The display apparatus 1 may be stretched in the third direction (e.g., a z direction or a -z direction) by an external force applied by a person’s body part or an external object. According to some embodiments, FIG. 2E illustrates that a part of the display apparatus 1, for example, a portion of the display area DA, protrudes in the z direction. According to some embodiments, a part of the display apparatus 1, for example, a portion of the display area DA, may protrude along the -z direction (or be recessed along the z direction).

Although the display apparatus 1 is stretched in the first direction, the second direction, and/or the third direction in FIGS. 2A to 2E, embodiments according to the present disclosure are not limited thereto. According to some embodiments, the display apparatus 1 may be deformed, for example, bent or twisted, into various irregular shapes along two or more axes.

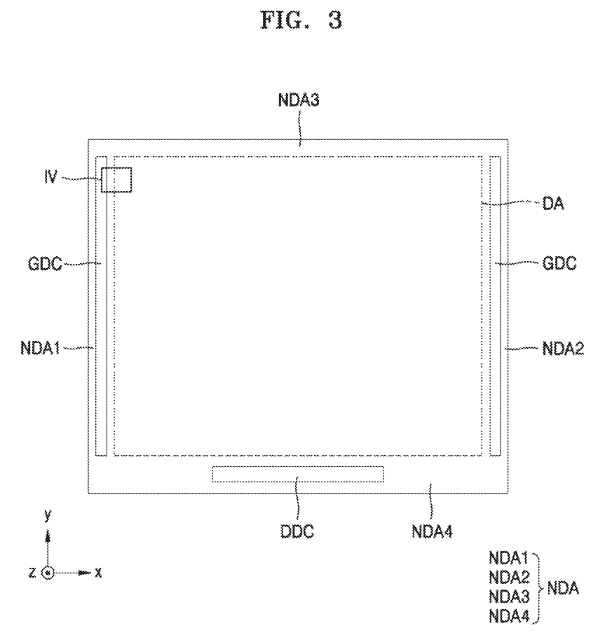

FIG. 3 is a plan view schematically illustrating the display apparatus 1, according to some embodiments of the present disclosure.

A plurality of pixels may be arranged in the display area DA of the display apparatus 1. Each pixel may include sub-pixels emitting light of different colors. A light-emitting element corresponding to each sub-pixel may be located in the display area DA. A circuit for applying electrical signals to the light-emitting elements located in the display area DA and transistors electrically connected to the light-emitting elements may be located in the non-display area NDA around the display area DA. A gate driving circuit GDC may be located in a first non-display area NDA1 and a second non-display area NDA2 located on both sides of the display area DA. The gate driving circuit GDC may include drivers for applying electrical signals to gate electrodes of the transistors electrically connected to the light-emitting elements. Although the gate driving circuit GDC is located in each of the first non-display area NDA1 and the second non-display area NDA2 in FIG. 3, embodiments according to the present disclosure are not limited thereto. According to some embodiments, the gate driving circuit GDC may be located in any one of the first non-display area NDA1 and the second non-display area NDA2.

A data driving circuit DDC may be located in a third non-display area NDA3 and/or a fourth non-display area NDA4 connecting the first non-display area NDA1 to the second non-display area NDA2. According to some embodiments, in FIG. 3, the data driving circuit DDC is located in the fourth non-display area NDA4. According to some embodiments, the data driving circuit DDC may be located in each of the third non-display area NDA3 and the fourth non-display area NDA4.

Although the data driving circuit DDC is located in the fourth non-display area NDA4 of the display apparatus 1 in FIG. 3, embodiments according to the present disclosure are not limited thereto. According to some embodiments, the display apparatus 1 may further include a flexible circuit board electrically connected through a terminal unit located in the fourth non-display area NDA4, and the data driving circuit DDC may be located on the flexible circuit board.

According to some embodiments, an elongation of the non-display area NDA may be equal to or less than an elongation of the display area DA. According to some embodiments, an elongation of the non-display area NDA may be different for each area. For example, the first non-display area NDA1, the second non-display area NDA2, and the third non-display area NDA3 may have the same (or substantially the same) elongation, but an elongation of the fourth non-display area NDA4 may be less than that of each of the first non-display area NDA1, the second non-display area NDA2, and the third non-display area NDA3. The term ‘elongation’ used herein refers to a value indicating a change (ΔL/L) in a length of the display apparatus 1 without physical damage to the display apparatus 1 when an external force is applied to the display apparatus 1. Here, ΔL denotes the amount of change in a length of the display apparatus, and L denotes an initial length of the display apparatus.

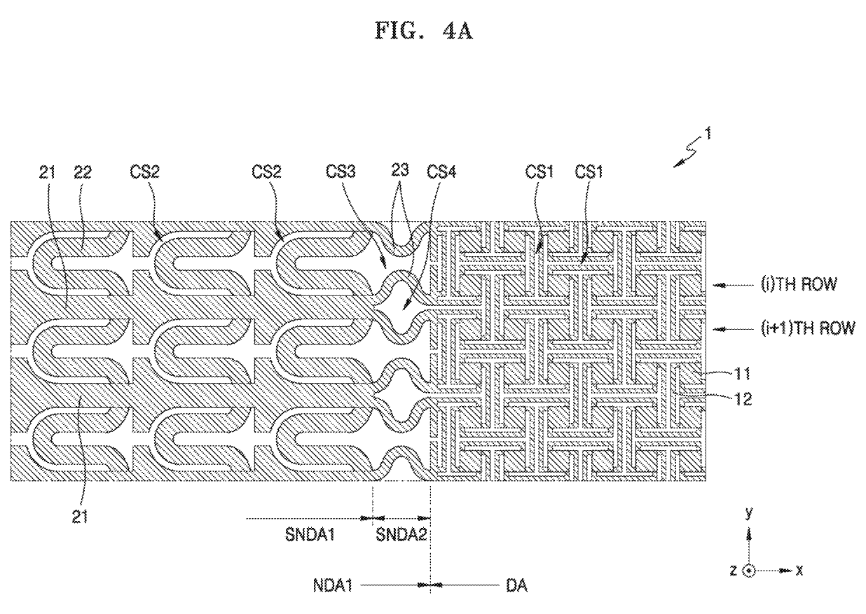

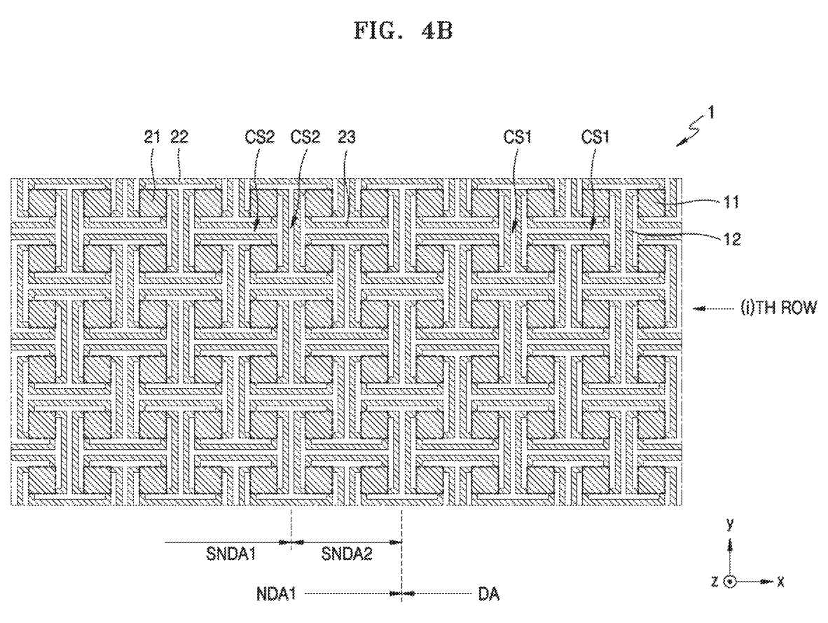

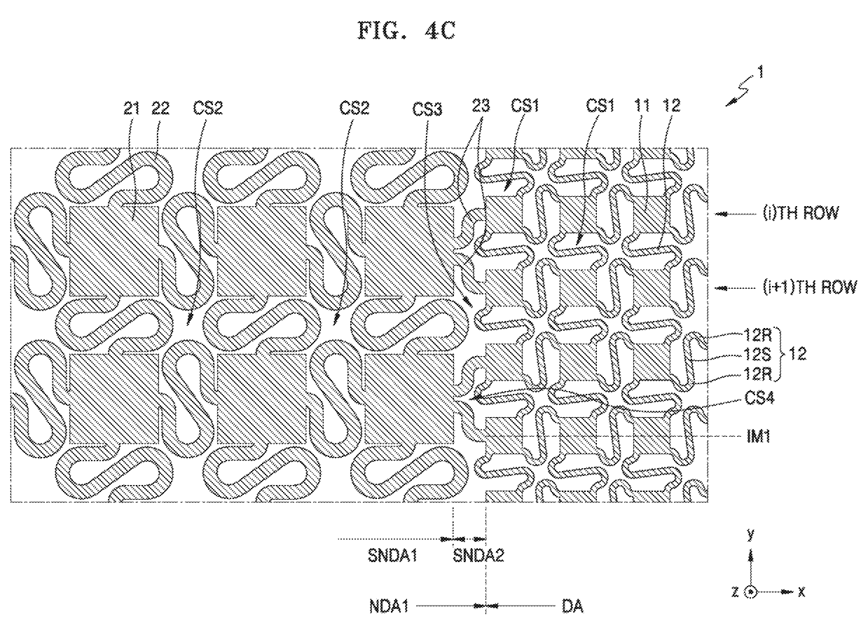

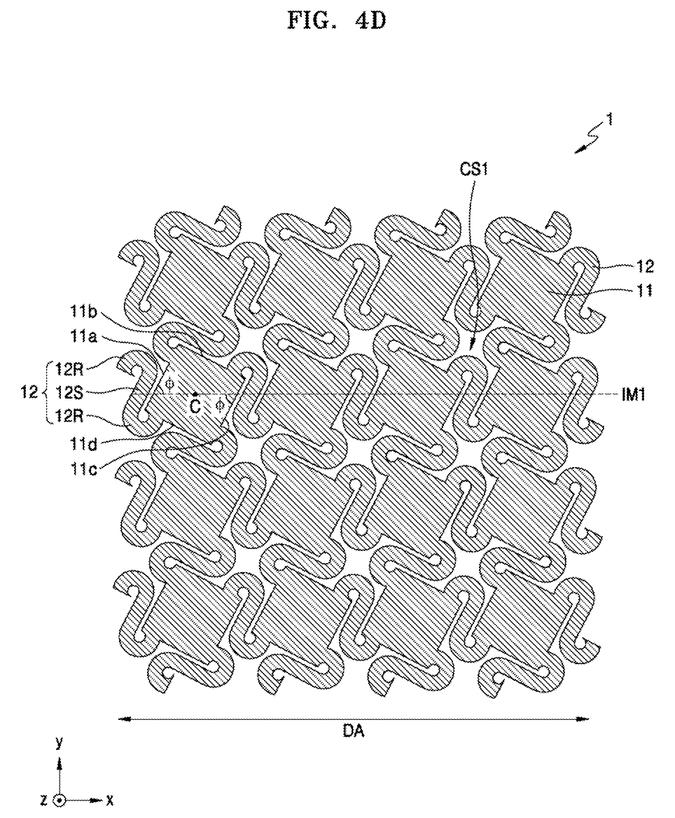

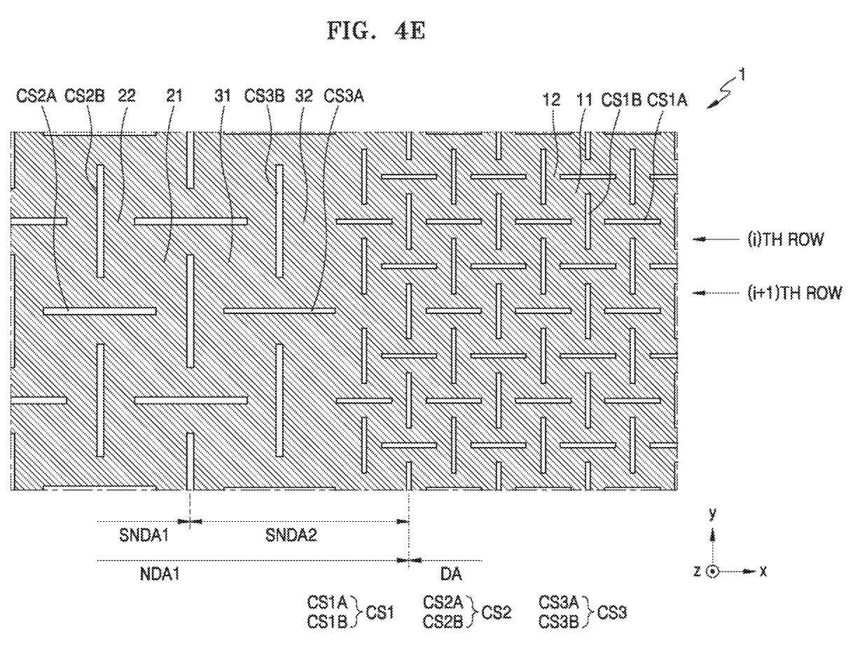

FIG. 4A is an enlarged plan view illustrating a portion IV of the display apparatus 1 of FIG. 3, according to some embodiments of the present disclosure.

Referring to FIG. 4A, the display apparatus 1 may include first island portions 11 spaced apart from each other in the first direction (e.g., the x direction or the -x direction) and the second direction (e.g., the y direction or the -y direction) and first bridge portions 12 connecting adjacent first island portions 11 in the display area DA.

Each first island portion 11 may be connected to a plurality of first bridge portions 12. For example, each first island portion 11 may be connected to four first bridge portions 12. Two first bridge portions 12 may be located on both sides of the first island portion 11 along the first direction (e.g., the x direction or the -x direction), and the remaining two first bridge portions 12 may be located on both sides of the first island portion 11 along the second direction (e.g., the y direction or the -y direction). According to some embodiments, the four first bridge portions 12 may be respectively connected to four sides of the first island portion 11. Each of the four first bridge portions 12 may be adjacent to each of corners of the first island portion 11.

The first bridge portions 12 may be spaced apart from each other by a first opening CS1 located between the first bridge portions 12. According to some embodiments, the first opening CS1 having a substantially H shape and the first opening CS1 having a substantially I shape obtained by rotating the H shape by 90 degrees may be alternately and repeatedly arranged along the first direction (e.g., the x direction or the -x direction) and the second direction (e.g., the y direction or the -y direction). Both ends of each first bridge portion 12 may be respectively connected to adjacent first island portions 11, and one side of each first bridge portion 12 may be spaced apart from one side of the adjacent first island portion 11 and/or one side of another first bridge portion 12 by the first opening CS1.

The display apparatus 1 may include second island portions 21 spaced apart from each other and second bridge portions 22 connecting adjacent second island portions 21 in the non-display area, for example, the first non-display area NDA1 of FIG. 4A.

Each second island portion 21 may extend along the first direction (e.g., the x direction or the -x direction). The second island portions 21 may be spaced apart from each other along the second direction (e.g., the y direction or the -y direction) intersecting the first direction (e.g., the x direction or the -x direction). Each second island portion 21 may include drivers of the gate driving circuit GDC (see FIG. 2) described with reference to FIG. 3.

The second bridge portion 22 may have a serpentine shape. A length of the second bridge portion 22 may be greater than a shortest distance between the second island portions 21 adjacent to each other along the second direction (e.g., the y direction or the -y direction). According to some embodiments, the second bridge portion 22 may have a substantially omega (Ω) shape that is convex toward the first direction (e.g., the x direction or the -x direction). The second bridge portions 22 may be located between adjacent second island portions 21, but may be spaced apart from each other.

The second bridge portions 22 between adjacent second island portions 21 may be spaced apart from each other by a second opening CS2. Between adjacent second island portions 21, the second openings CS2 and the second bridge portions 22 may be alternately arranged along the first direction (e.g., the x direction or the -x direction). The second openings CS2 may have the same shape. Both ends of each second bridge portion 22 may be connected to adjacent second island portions 21, and one side of each second bridge portion 22 may be spaced apart from one side of the adjacent second island portion 21 and/or one side of another second bridge portion 22 by the second opening CS2.

Any one second island portion 21 located in the first non-display area NDA1 may correspond to the first island portions 11 of a plurality of rows arranged in the display area DA. For example, any one second island portion 21 located in the first non-display area NDA1 may correspond to the first island portions 11 arranged in an (i)^{th} row and the first island portions 11 arranged in an (i+1)^{th} row in the display area DA (where i is a positive number greater than 0). Although one second island portion 21 corresponds to the first island portions 11 arranged in two rows in FIG. 4A, embodiments according to the present disclosure are not limited thereto. According to some embodiments, any one second island portion 21 located in the first non-display area NDA1 may correspond to the first island portions 11 arranged in n rows in the display area DA (where n is a positive number of 3 or more).

The non-display area, for example, the first non-display area NDA1, may include a first sub-non-display area SNDA1 in which the second island portions 21 and the second bridge portions 22 are located, and a second sub-non-display area SNDA2 between the first sub-non-display area SNDA1 and the display area DA. Third bridge portions 23 for connecting the display area DA and the first sub-non-display area SNDA1 to each other may be located in the second sub-non-display area SNDA2. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. According to some embodiments, a shape of the third bridge portion 23 may be different from a shape of each of the first bridge portion 12 and the second bridge portion 22. According to some embodiments, as shown in FIG. 4A, the third bridge portion 23 may have a substantially omega (Ω) shape that is convex toward the second direction (e.g., the y direction or the -y direction). Adjacent third bridge portions 23 arranged along the second direction (e.g., the y direction or the -y direction) may have a symmetrical structure in which one of the adjacent third bridge portions 23 is convex in the y direction and the other is convex in the -y direction. A third opening CS3 and a fourth opening CS4 having different shapes may be repeatedly arranged between the third bridge portions 23. A width of the third bridge portion 23 may be different from a width of the first bridge portion 12 and a width of the second bridge portion 22. According to some embodiments, a width of the third bridge portion 23 may be greater than a width of the first bridge portion 12 and may be less than a width of the second bridge portion 22.

FIG. 4A illustrates that the second island portion 21 and the second bridge portion 22 of the non-display area, for example, the first non-display area NDA1, have different shapes from the first island portion 11 and the first bridge portion 12 of the display area DA. According to some embodiments of the present disclosure, the second island portion 21 and the second bridge portion 22 of the non-display area may have the same shape as the first island portion 11 and the first bridge portion 12 of the display area DA.

FIG. 4B is an enlarged plan view illustrating the portion IV of the display apparatus 1 of FIG. 3, according to some embodiments of the present disclosure.

Referring to FIG. 4B, the display apparatus 1 includes the first island portions 11 spaced apart from each other and the first bridge portions 12 spaced apart from each other by the first opening CS1 and connecting adjacent first island portions 11 in the display area DA. A structure of the display area DA of FIG. 4B may be the same as a structure of the display area DA described with reference to FIG. 4A.

The display apparatus 1 may include the second island portions 21 and the second bridge portions 22 in the non-display area, for example, the first non-display area NDA1. According to some embodiments, the second island portions 21 and the second bridge portions 22 may have the same (or substantially the same) shape as the first island portions 11 and the first bridge portions 12.

The second island portions 21 may be spaced apart from each other in the first direction (e.g., the x direction or the -x direction) and the second direction (e.g., the y direction or the -y direction) in the non-display area, for example, the first non-display area NDA1. Each of the second bridge portions 22 may connect adjacent second island portions 21. The second bridge portions 22 may be spaced apart from each other by the second opening CS2 located between the second bridge portions 22.

The second opening CS2 may have the same (or substantially the same) shape as the first opening CS1. For example, the second opening CS2 having a substantially H shape and the second opening CS2 having a substantially I shape may be alternately and repeatedly arranged in the non-display area, for example, the first non-display area NDA1. Both ends of each second bridge portion 22 may be respectively connected to adjacent second island portions 21, and one side of each second bridge portion 22 may be spaced apart from one side of the adjacent second island portion 21 and/or one side of another second bridge portion 22 by the second opening CS2.

Each second island portion 21 may be connected to four second bridge portions 22. Each second island portion 21 may include drivers of the gate driving circuit GDC (see FIG. 2) described with reference to FIG. 3.

The second island portions 21 of any one row located in the first non-display area NDA1 may correspond to the first island portions 11 of any one row arranged in the display area DA. For example, the second island portions 21 arranged in an (i)^{th} row along the first direction (e.g., the x direction or the -x direction) in the first non-display area NDA1 may correspond to the first island portions 11 arranged in the same row, for example, an (i)^{th} row, in the display area DA (where i is a positive number greater than 0).

The display apparatus 1 may include the third bridge portions 23 located in the second sub-non-display area SNDA2 for connecting the display area DA and the first sub-non-display area SNDA1 to each other. The non-display area, for example, the first non-display area NDA1, may include the first sub-non-display area SNDA1 in which the second island portions 21 and the second bridge portions 22 are located, and the second sub-non-display area SNDA2 including the third bridge portions 23 and located between the first sub-non-display area SNDA1 and the display area DA. The third bridge portion 23 may be the same (or substantially the same) as the first bridge portion 12 and the second bridge portion 22. For example, a width of the third bridge portion 23 may be the same as a width of the first bridge portion 12 and a width of the second bridge portion 22.

FIG. 4C is an enlarged plan view illustrating the portion IV of the display apparatus 1 of FIG. 3, according to some embodiments of the present disclosure.

Referring to FIG. 4C, the display apparatus 1 may include the first island portions 11 spaced apart from each other in the first direction (e.g., the x direction or the -x direction) and the second direction (e.g., the y direction or the -y direction) and the first bridge portions 12 connecting adjacent first island portions 11 in the display area DA.

The first bridge portions 12 may be spaced apart from each other by the first opening CS1 located between the first bridge portions 12. The first bridge portion 12 may have a serpentine shape. For example, as shown in FIG. 4C, the first bridge portion 12 may have a substantially ‘letter S’ shape by including two round portions 12R and a straight portion 12S between the two round portions 12R.

Each first island portion 11 may be connected to a plurality of first bridge portions 12. For example, each first island portion 11 may be connected to four first bridge portions 12. Two first bridge portions 12 may be located on both sides of the first island portion 11 along the first direction (e.g., the x direction or the -x direction), and the remaining two first bridge portions 12 may be located on both sides of the first island portion 11 along the second direction (e.g., the y direction or the -y direction). The four first bridge portions 12 may be respectively connected to four sides of the first island portion 11. Each of the four first bridge portions 12 may be adjacent to each of corners of the first island portion 11.

The display apparatus 1 may include the second island portions 21 spaced apart from each other in the first direction (e.g., the x direction or the -x direction) and the second direction (e.g., the y direction or the -y direction) and the second bridge portions 22 connecting adjacent second island portions 21 in the non-display area, for example, the first non-display area NDA1 of FIG. 4C.

The second bridge portions 22 may be spaced apart from each other by the second opening CS2 located between the second bridge portions 22. The second bridge portion 22 may have a serpentine shape. For example, as shown in FIG. 4C, the second bridge portion 22 may have a substantially ‘letter S’ shape. A size and/or a width of the second bridge portion 22 may be different from a size and/or a width of the first bridge portion 12. For example, a size and/or a width of the second bridge portion 22 may be greater than a size and/or a width of the first bridge portion 12. A radius of curvature of a rounded portion of the second bridge portion 22 may be different from a radius of curvature of a rounded portion of the first bridge portion 12. For example, a radius of curvature of a rounded portion of the second bridge portion 22 may be greater than a radius of curvature of a rounded portion of the first bridge portion 12.

Each second island portion 21 may be connected to a plurality of second bridge portions 22. Each second island portion 21 may be connected to four second bridge portions 22. Two second bridge portions 22 may be located on both sides of the second island portion 21 along the first direction (e.g., the x direction or the -x direction), and the remaining two second bridge portions 22 may be located on both sides of the second island portion 21 along the second direction (e.g., the y direction or the -y direction). According to some embodiments, the four second bridge portions 22 may be respectively connected to four sides of the second island portion 21. Each second bridge portion 22 may be connected to a central portion of each side of the second island portion 21.

The second island portions 21 of any one row located in the first non-display area NDA1 may correspond to the first island portions 11 of a plurality of rows arranged in the display area DA. For example, the second island portions 21 of any one row located in the first non-display area NDA1 may correspond to the first island portions 11 arranged in an (i)^{th} row and the first island portions 11 arranged in an (i+1)^{th} row of the display area DA (where i is a positive number greater than 0). According to some embodiments, the second island portions 21 of any one row may correspond to the first island portions 11 arranged in n rows (where n is a positive number of 3 or more).

The non-display area, for example, the first non-display area NDA1, may include the first sub-non-display area SNDA1 in which the second island portions 21 and the second bridge portions 22 are located, and the second sub-non-display area SNDA2 between the first sub-non-display area SNDA1 and the display area DA. Third bridge portions 23 for connecting the display area DA and the first sub-non-display area SNDA1 to each other may be located in the second sub-non-display area SNDA2. One end of the third bridge portion 23 may be connected to the second island portion 21, and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. According to some embodiments, a shape of the third bridge portion 23 may be different from a shape of each of the first bridge portion 12 and the second bridge portion 22. A width of the third bridge portion 23 may be different from a width of the first bridge portion 12 and a width of the second bridge portion 22. A width of the third bridge portion 23 may be greater than a width of the first bridge portion 12 and may be less than a width of the second bridge portion 22. The third opening CS3 and the fourth opening CS4 having different shapes may be alternately located between the third bridge portions 23 in the second direction (e.g., the y direction or the -y direction).

FIG. 4D is an enlarged plan view illustrating a part of the display apparatus 1, that is, the display area DA of FIG. 3, according to some embodiments of the present disclosure.

Referring to FIG. 4D, the display apparatus 1 may include the first island portions 11 spaced apart from each other in the first direction (e.g., the x direction or the -x direction) and the second direction (e.g., the y direction or the -y direction) and the first bridge portions 12 connecting adjacent first island portions 11 in the display area DA. The first bridge portions 12 may be spaced apart from each other by the first opening CS1 located between the first bridge portions 12.

According to some embodiments, at least one of sides of the first island portion 11 may be oblique to a virtual line connecting centers C of the first island portions 11 along the first direction (e.g., the x direction or the -x direction) and/or the second direction (e.g., the y direction or the -y direction). In this regard, in FIG. 4D, the first island portion 11 includes first to fourth sides 11a, 11b, 11c, and 11d, and the first to fourth sides 11a, 11b, 11c, and 11d extend in a direction oblique to a first virtual line IM1 connecting the centers C of the first island portions 11. Although the first virtual line IM1 extends in the first direction (e.g., the x direction or the -x direction) in FIG. 4D, the first virtual line IM1 may extend along the second direction (e.g., the y direction or the -y direction).

According to some embodiments, the first side 11a and the third side 11c parallel to each other may intersect the first virtual line IM1. A smaller angle (hereinafter, referred to as a minor angle Ф) between the first side 11a and the first virtual line IM1 may be greater than 0° and less than 90°. A minor angle Ф between the third side 11c and the first virtual line IM1 may be greater than 0° and less than 90°.

Each first island portion 11 may be connected to a plurality of first bridge portions 12. For example, each first island portion 11 may be connected to four first bridge portions 12. Two first bridge portions 12 may be located on both sides of the first island portion 11 along the first direction (e.g., the x direction or the -x direction), and the remaining two first bridge portions 12 may be located on both sides of the first island portion 11 along the second direction (e.g., the y direction or the -y direction).

The first bridge portion 12 may have a serpentine shape. For example, as shown in FIG. 4D, the first bridge portion 12 may have a substantially ‘letter S’ shape by including two round portions 12R and one straight portion 12S between the two round portions 12R.

According to some embodiments, the straight portion 12S may be parallel (or substantially parallel) to a side of the first island portion 11 adjacent to the straight portion 12S as shown in FIG. 4D. For example, the straight portion 12S of each of the first bridge portions 12 located on both sides of the first island portion 11 along the first direction (e.g., the x direction or the -x direction) may be parallel (or substantially parallel) to a side (e.g., each of the first side 11a and the third side 11c) of the first island portion 11. The straight portion 12S of each of the first bridge portions 12 located on both sides of the first island portion 11 along the second direction (e.g., the y direction or the -y direction) may be parallel (or substantially parallel) to a side (e.g., each of the second side 11b and the fourth side 11d) of the first island portion 11.

Each of the first island portions 11 of FIG. 4D may be obtained by rotating each of the first island portions 11 of FIG. 4C by a first angle (e.g., an acute angle) with respect to the center C. Accordingly, at least one of sides of the first island portion 11 may be oblique to a virtual line connecting the centers C of the first island portions 11 along the first direction (e.g., the x direction or the -x direction) and/or the second direction (e.g., the y direction or the -y direction). According to the arrangement of the first island portion 11 and/or the structure of the first bridge portion 12 described above, the area of the first opening CS1 of FIG. 4D may be less than the area of the first opening CS1 of FIG. 4C, and thus, the display apparatus 1 according to some embodiments as illustrated in FIG. 4D may provide a relatively high resolution image.

Although the straight portion 12S of the first bridge portion 12 is parallel (or substantially parallel) to a side of the first island portion 11 adjacent to the straight portion 12S in FIG. 4D, embodiments according to the present disclosure are not limited thereto. According to some embodiments, the straight portion 12S of the first bridge portion 12 may be oblique to a side of the first island portion 11 adjacent to the straight portion 12S as shown in FIG. 4C.

According to some embodiments, a structure of the first non-display area NDA1 (see FIG. 3) of the display apparatus not disclosed in FIG. 4D may be the same as a structure of the display area DA disclosed in FIG. 4D. According to some embodiments, a structure of the first non-display area NDA1 (see FIG. 3) of the display apparatus 1 not disclosed in FIG. 4D may be the same (or substantially the same) as a structure of the display area DA disclosed in FIG. 4D, and the area of the second island portion disclosed in the first non-display area NDA1 (see FIG. 3) may be greater than the area of the first island portion 11. In this case, one second island portion may correspond to a plurality of first island portions 11 arranged in adjacent rows as described with reference to FIG. 4C. According to some embodiments, a structure of the first non-display area NDA1 (see FIG. 3) of the display apparatus 1 not disclosed in FIG. 4D may be the same (or substantially the same) as a structure of the first non-display area NDA1 illustrated in any one of FIGS. 4A to 4C. As such, a structure of the first non-display area NDA1 (see FIG. 3) may be selected in various ways within a range disclosed in the present specification.

FIG. 4E is an enlarged plan view illustrating the portion IV of the display apparatus 1 of FIG. 3, according to some embodiments of the present disclosure.

Referring to FIG. 4E, the display apparatus 1 includes the first island portions 11 spaced apart from each other and the first bridge portions 12 spaced apart from each other by the first opening CS1 and connecting adjacent first island portions 11 in the display area DA.

The first opening CS1 may have a bar shape. The first opening CS1 may include a first sub-opening CS1A extending in the first direction (e.g., the x direction or the -x direction) and a second sub-opening CS1B extending in the second direction (e.g., the y direction or the -y direction). Each of the first sub-opening CS1A and the second sub-opening CS1B may have a bar shape. The first sub-opening CS1A and the second sub-opening CS1B may have the same (or substantially the same) width and the same length. A length of each of the first sub-opening CS1A and the second sub-opening CS1B is a value measured along an extension direction, and a width of each of the first sub-opening CS1A and the second sub-opening CS1B is a value measured along a direction perpendicular to a longitudinal direction (e.g., the extension direction).

The display apparatus 1 may include the second island portions 21 and the second bridge portions 22 in the non-display area, for example, the first sub-non-display area SNDA1. The second island portions 21 may be spaced apart from each other in the first direction (e.g., the x direction or the -x direction) and the second direction (e.g., the y direction or the -y direction) in the non-display area, for example, the first sub-non-display area SNDA1. Each of the second bridge portions 22 may connect adjacent second island portions 21. The second bridge portions 22 may be spaced apart from each other by the second opening CS2 located between the second bridge portions 22.

The second opening CS2 may have a bar shape. The second opening CS2 may include a first sub-opening CS2A extending in the first direction (e.g., the x direction or the -x direction) and a second sub-opening CS2B extending in the second direction (e.g., the y direction or the -y direction). Each of the first sub-opening CS2A and the second sub-opening CS2B may have a bar shape. The first sub-opening CS2A and the second sub-opening CS2B may have the same (or substantially the same) width and the same length. Each second island portion 21 may be connected to four second bridge portions 22. Each second island portion 21 may include drivers of the gate driving circuit GDC (see FIG. 2) described with reference to FIG. 3. Some of drivers of the gate driving circuit GDC (see FIG. 2) may also be located in the second sub-non-display area SNDA2. For example, some third island portions 31 may include some drivers.

Any one second island portion 21 located in the first non-display area NDA1 may correspond to the first island portions 11 of a plurality of rows arranged in the display area DA. For example, any one second island portion 21 located in the first non-display area NDA1 may correspond to the first island portions 11 arranged in an (i)^{th} row and the first island portions 11 arranged in an (i+1)^{th} row in the display area DA (where i is a positive number greater than 0). Although one second island portion 21 corresponds to the first island portions 11 arranged in two rows in FIG. 4E, embodiments according to the present disclosure are not limited thereto. According to some embodiments, any one second island portion 21 located in the first non-display area NDA1 may correspond to the first island portions 11 arranged in n rows in the display area DA (where n is a positive number of 3 or more).

The display apparatus 1 may include the third island portions 31 and third bridge portions 32 located in the second sub-non-display area SNDA2 for connecting the display area DA and the first sub-non-display area SNDA1 to each other. Adjacent third island portions 31 may be spaced apart from each other by the third opening CS3 and may be connected to each other by the third bridge portions 32.

The third opening CS3 may have a bar shape. The third opening CS3 may include a first sub-opening CS3A extending in the first direction (e.g., the x direction or the -x direction) and a second sub-opening CS3B extending in the second direction (e.g., the y direction or the -y direction). Each of the first sub-opening CS3A and the second sub-opening CS3B may have a bar shape. The first sub-opening CS3A and the second sub-opening CS3B may have different widths and/or lengths.

According to some embodiments, a length of the first sub-opening CS3A of the third opening CS3 in the first direction (e.g., the x direction or the -x direction) may be equal to or greater than a length of the second sub-opening CS3B of the third opening CS3 in the second direction (e.g., the y direction or the -y direction). A width of the first sub-opening CS3A of the third opening CS3 in the second direction (e.g., the y direction or the -y direction) may be less than a width of the second sub-opening CS3B of the third opening CS3 in the first direction (e.g., the x direction or the -x direction).

According to some embodiments, a length of the first sub-opening CS3A of the third opening CS3 in the first direction (e.g., the x direction or the -x direction) may be the same as a length of the first sub-opening CS2A of the second opening CS2 in the first direction (e.g., the x direction or the -x direction) and may be greater than a length of the first sub-opening CS1A of the first opening CS1 in the first direction (e.g., the x direction or the -x direction). A width of the first sub-opening CS3A of the third opening CS3 in the second direction (e.g., the y direction or the -y direction) may be less than a width of the first sub-opening CS2A of the second opening CS2 in the second direction (e.g., the y direction or the -y direction) and may be the same as a width of the first sub-opening CS1A of the first opening CS1 in the second direction (e.g., the y direction or the -y direction).

According to some embodiments, a length of the second sub-opening CS3B of the third opening CS3 in the second direction (e.g., the y direction or the -y direction) may be the same as a length of the second sub-opening CS2B of the second opening CS2 in the second direction (e.g., the y direction or the -y direction) and may be greater than a length of the second sub-opening CS1B of the first opening CS1 in the second direction (e.g., the y direction or the -y direction). A width of the second sub-opening CS3B of the third opening CS3 in the first direction (e.g., the x direction or the -x direction may be the same as a width of the second sub-opening CS2B of the second opening CS2 in the first direction (e.g., the x direction or the -x direction) and may be greater than a width of the second sub-opening CS1B of the first opening CS1 in the first direction (e.g., the x direction or the -x direction).

FIG. 5 is a cross-sectional view schematically illustrating the first island portion 11 and the first bridge portion 12 located in the display area DA of the display apparatus 1, according to some embodiments of the present disclosure.

Referring to FIG. 5, the first island portion 11 and the first bridge portion 12 located in the display area DA may be spaced apart from each other with the first opening CS1 therebetween. The first island portion 11 may include light-emitting elements LED and a circuit, for example, a pixel driving circuit unit PC, for driving light-emitting elements electrically connected thereto, and the first bridge portion 12 may include a connection wiring WL electrically connected to the pixel driving circuit units PC located in adjacent first island portions 11.

Regarding the first island portion 11, a buffer layer 111 including an inorganic insulating material may be located on the substrate 100, and the pixel driving circuit unit PC may be located on the buffer layer 111. An insulating layer IL including an inorganic insulating material and/or an organic insulating material may be located between the pixel driving circuit unit PC and the light-emitting element LED. The light-emitting element LED may be located on the insulating layer IL and may be electrically connected to the corresponding pixel driving circuit unit PC. The light-emitting elements LED may emit light of different colors or light of the same color. According to some embodiments, the light-emitting elements LED may emit red light, green light, and blue light. According to some embodiments, the light-emitting elements LED may emit white light. According to some embodiments, the light-emitting elements LED may respectively emit red light, green light, blue light, and white light.

The substrate 100 may include a polymer resin such as polyethersulfone, polyarylate, polyether imide, polyethylene naphthalate, polyethylene terephthalate, polyphenylene sulfide, polyimide, polycarbonate, cellulose triacetate, or cellulose acetate propionate. According to some embodiments, the substrate 100 may have a single-layer structure including the polymer resin. According to some embodiments, the substrate 100 may have a multi-layer structure including a base layer including the polymer resin and a barrier layer including an inorganic insulating material. The substrate 100 including the polymer resin may be flexible, rollable, or bendable.

According to some embodiments, although three pixel driving circuit units PC are located in each first island portion 11 and three light-emitting elements LED are respectively connected to the pixel driving circuit units PC in FIG. 5, embodiments according to the present disclosure are not limited thereto. According to some embodiments, the number of pixel driving circuit units PC and light-emitting elements LED located in the first island portion 11 may be one, two, or four or more.

An encapsulation layer 300 may be located on the light-emitting element LED, and may protect the light-emitting element LED from an external force and/or moisture penetration. The encapsulation layer 300 may include an inorganic encapsulation layer and/or an organic encapsulation layer. According to some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. According to some embodiments, the encapsulation layer 300 may include an organic material such as resin. According to some embodiments, the encapsulation layer 300 may include urethane epoxy acrylate. The encapsulation layer 300 may include a photosensitive material such as a photoresist.

Regarding the first bridge portion 12, the insulating layer IL including an organic insulating material may be located on the substrate 100. The first bridge portion 12 that is relatively highly deformed when the display apparatus 1 is stretched may not include a layer including an inorganic insulating material that is prone to cracks, unlike the first island portion 11.

According to some embodiments, the substrate 100 corresponding to the first bridge portion 12 may have the same stacked structure as the substrate 100 corresponding to the first island portion 11. According to some embodiments, the substrate 100 corresponding to the first bridge portion 12 and the substrate 100 corresponding to the first island portion 11 may be polymer resin layers formed together in the same process. According to some embodiments, the substrate 100 corresponding to the first bridge portion 12 may have a stacked structure different from that of the substrate 100 corresponding to the first island portion 11. According to some embodiments, the substrate 100 corresponding to the first bridge portion 12 may have a multi-layer structure including a base layer including a polymer resin and a barrier layer including an inorganic insulating material, and the substrate 100 corresponding to the first bridge portion 12 may have a structure including a polymer resin layer without a layer including an inorganic insulating material.

As described above, the connection wirings WL of the first bridge portion 12 may be signal lines (e.g., a gate line and a data line) for providing an electrical signal to a transistor included in the pixel driving circuit unit PC of the first island portion 11 or voltage lines (e.g., a driving voltage line and an initialization voltage line) for providing a voltage. The encapsulation layer 300 may also be located in the first bridge portion 12. According to some embodiments, the encapsulation layer 300 may not be located in the first bridge portion 12.

Referring to FIGS. 4A to 4E and 5, the substrate 100 corresponding to the first island portion 11 and the substrate 100 corresponding to the first bridge portion 12 may be connected to each other. In other words, the plan view of FIGS. 4A to 4E may be the same (or substantially the same) as a plan view of the substrate 100 of FIG. 5. In other words, the substrate 100 may include an area corresponding to the first island portion 11, an area corresponding to the first bridge portion 12, and an opening 100OP1 having the same shape as the first opening CS1.

Likewise, the encapsulation layer 300 corresponding to the first island portion 11 and the encapsulation layer 300 corresponding to the first bridge portion 12 may be connected to each other. For example, the plan view of FIGS. 4A to 4E may be the same (or substantially the same) as a plan view of the encapsulation layer 300. In other words, the encapsulation layer 300 may include an area corresponding to the first island portion 11, an area corresponding to the first bridge portion 12, and an opening 300OP1 having the same shape as the first opening CS1.

A circuit-light-emitting element layer 200 between the substrate 100 and the encapsulation layer 300 may include the buffer layer 111, the pixel driving circuit unit PC, the connection wiring WL, the insulating layer IL, and the light-emitting element LED. Like the substrate 100, the plan view of FIGS. 4A to 4E may be the same (or substantially the same) as a plan view of the circuit-light-emitting element layer 200. In other words, the circuit-light-emitting element layer 200 may include an opening 200OP1 having the same shape as the first opening CS1.

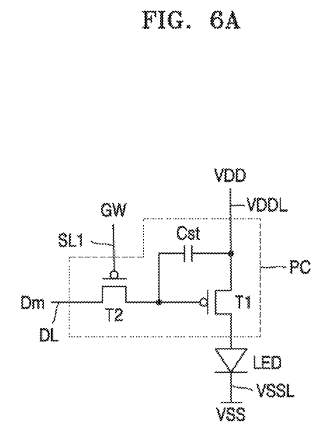

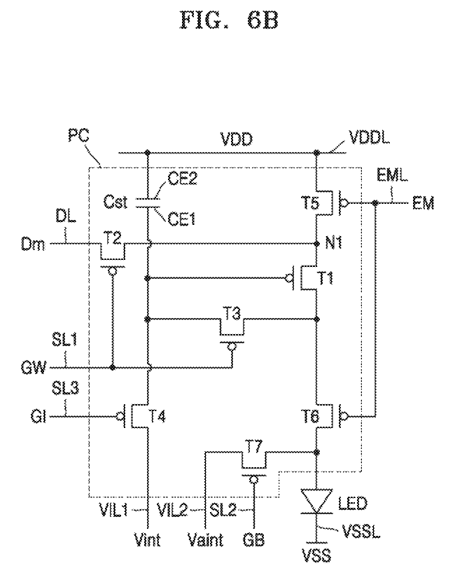

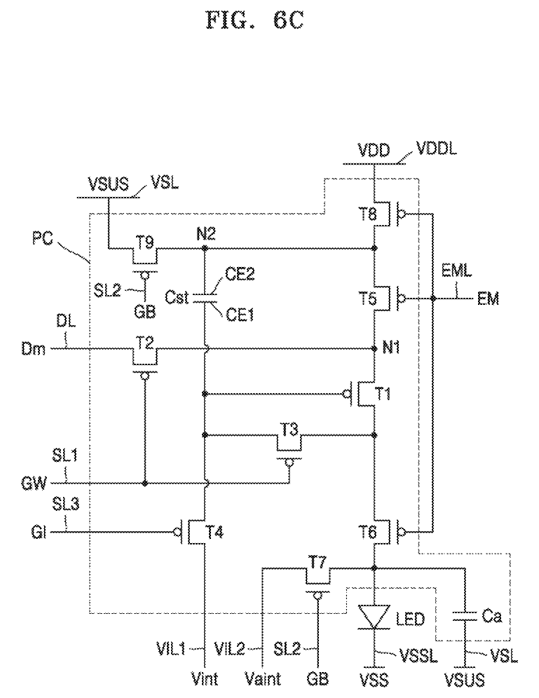

FIGS. 6A to 6C are equivalent circuit diagrams illustrating a sub-pixel of the display apparatus 1, according to some embodiments of the present disclosure. Although FIGS. 6A to 6C illustrate various components in a sub-pixel according to some embodiments, embodiments according to the present disclosure are not limited thereto, and according to various embodiments, the sub-pixel may include additional components or fewer components without departing from the spirit and scope of embodiments according to the present disclosure.

Referring to FIG. 6A, the light-emitting element LED corresponding to a sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to a signal line and a voltage line. The signal line may include a gate line such as a first scan line SL1 and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit a data signal Dm input from the data line DL to the first transistor T1 according to the first scan signal GW input from the first scan line SL1.

The storage capacitor Cst may be electrically connected to the second transistor T2 and the first voltage line VDDL, and may store a voltage corresponding to a difference between a voltage received from the second transistor T2 and a first power supply voltage VDD supplied by the first voltage line VDDL.

The first transistor T1 is a driving transistor and may control driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in response to a value of the voltage stored in the storage capacitor Cst. The light-emitting element LED may emit light having a certain luminance due to the driving current. A first electrode of the light-emitting element LED may be electrically connected to the first transistor T1, and a second electrode of the light-emitting element LED may be electrically connected to a second voltage line VSSL that supplies a second power supply voltage VSS.

Although the pixel driving circuit unit PC includes two transistors and one storage capacitor in FIG. 6A, according to some embodiments, the pixel driving circuit unit PC may include three or more transistors.

Referring to FIG. 6B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to signal lines and voltage lines. The signal lines may include gate lines such as a first scan line SL1, a second scan line SL2, a third scan line SL3, and an emission control line EML, and a data line DL. The voltage lines may include first and second initialization voltage lines VIL1 and VIL2, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting element LED to the pixel driving circuit unit PC.

The first transistor T1 may be electrically connected to the first voltage line VDDL via the fifth transistor T5, and may be electrically connected to the light-emitting element LED via the sixth transistor T6. The first transistor T1 functions as a driving transistor, and receives a data signal Dm according to a switching operation of the second transistor T2 and supplies driving current to the light-emitting element LED.

The second transistor T2 is a data write transistor and is electrically connected to the first scan line SL1 and the data line DL. The second transistor T2 is electrically connected to the first voltage line VDDL via the fifth transistor T5. The second transistor T2 is turned on according to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting element LED via the sixth transistor T6. The third transistor T3 may be turned on according to the first scan signal GW received through the first scan line SL1 to diode-connect the first transistor T1.

The fourth transistor T4 is a first initialization transistor and is electrically connected to the third scan line SL3 and the first initialization voltage line VIL1. The fourth transistor T4 is turned on according to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit located in a previous row with respect to the pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on according to an emission control signal EM received through the emission control line EML to form a current path through which the driving current may flow from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 may be turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a voltage difference between the first voltage line VDDL and the gate electrode of the first transistor T1.

Referring to FIG. 6C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to signal lines and voltage lines. The signal lines may include gate lines such as a first scan line SL1, a second scan line SL2, a third scan line SL3, and an emission control line EML, and a data line DL. The voltage lines may include first and second initialization voltage lines VIL1 and VIL2, a sustain voltage line VSL, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel driving circuit unit PC. The second initialization voltage line VIL2 may transmit a second initialization voltage Vaint for initializing a first electrode of the light-emitting element LED to the pixel driving circuit unit PC. The sustain voltage line VSL may provide a sustain voltage VSUS to a second node N2, for example, a second electrode CE2 of the storage capacitor Cst, in an initialization period and a data write period.

The first transistor T1 may be electrically connected to the first voltage line VDDL via the fifth transistor T5 and the eighth transistor T8, and may be electrically connected to the light-emitting element LED via the sixth transistor T6. The first transistor T1 functions as a driving transistor, and may supply driving current to the light-emitting element LED by receiving a data signal Dm according to a switching operation of the second transistor T2.

The second transistor T2 is electrically connected to the first scan line SL1 and the data line DL, and is electrically connected to the first voltage line VDDL via the fifth transistor T5 and the eighth transistor T8. The second transistor T2 is turned on according to a first scan signal GW received through the first scan line SL1 to perform a switching operation of transmitting the data signal Dm received through the data line DL to a first node N1.

The third transistor T3 is electrically connected to the first scan line SL1 and is electrically connected to the light-emitting element LED via the sixth transistor T6. The third transistor T3 is turned on according to the first scan signal GW received through the first scan line SL1 to diode-connect the first transistor T1 and compensate for a threshold voltage of the first transistor T1.

The fourth transistor T4 is electrically connected to the third scan line SL3 and the first initialization voltage line VIL1, and is turned on according to a third scan signal GI received through the third scan line SL3 to initialize a voltage of a gate electrode of the first transistor T1 by transmitting the first initialization voltage Vint from the first initialization voltage line VIL1 to the gate electrode of the first transistor T1. The third scan signal GI may correspond to a first scan signal of another pixel driving circuit unit located in a previous row with respect to the pixel driving circuit unit PC.

The fifth transistor T5, the sixth transistor T6, and the eighth transistor T8 are electrically connected to the emission control line EML, and are simultaneously turned on according to an emission control signal EM received through the emission control line EML to form a current path through which the driving current may flow from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB received through the second scan line SL2 to initialize the first electrode of the light-emitting element LED by transmitting the second initialization voltage Vaint from the second initialization voltage line VIL2 to the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on according to the second scan signal GB received through the second scan line SL2 to transmit the sustain voltage VSUS to the second node N2, for example, the second electrode CE2 of the storage capacitor Cst, in the initialization period and the data write period.

The eighth transistor T8 and the ninth transistor T9 may be electrically connected to the second node N2, for example, the second electrode CE2 of the storage capacitor Cst. According to some embodiments, the eighth transistor T8 may be turned off and the ninth transistor T9 may be turned on in the initialization period and the data write period, and the eighth transistor T8 may be turned on and the ninth transistor T9 may be turned off in an emission period. Because the sustain voltage VSUS is transmitted to the second node N2 in the initialization period and the data write period, the uniformity (e.g., long-range uniformity (LRU)) of luminance of the display apparatus according to a voltage drop of the first voltage line VDDL may be relatively improved.

The storage capacitor Cst includes a first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, thereby preventing or reducing an increase in black luminance when the sixth transistor T6 is turned off.

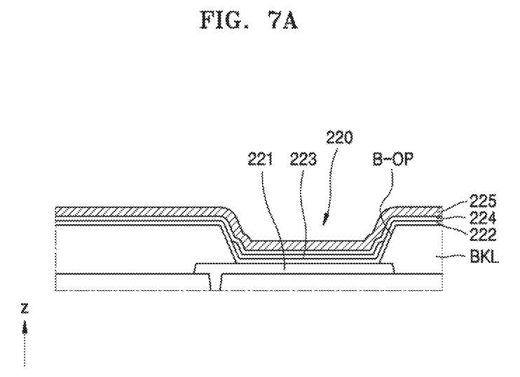

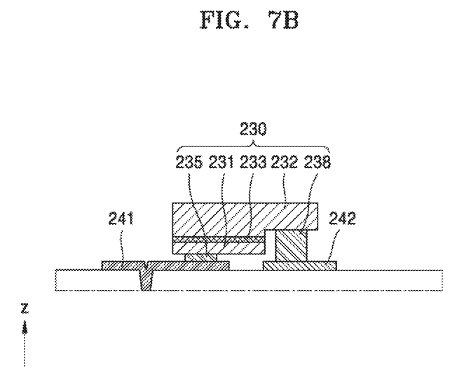

FIG. 7A is a cross-sectional view schematically illustrating a light-emitting element of a display apparatus, according to some embodiments of the present disclosure.

Referring to FIG. 7A, a light-emitting element according to some embodiments of the present disclosure may include an organic light-emitting diode 220 including an organic material. The organic light-emitting diode 220 may include a first electrode 221 located on an insulating layer, a second electrode 225 facing the first electrode 221, and an emission layer 223 located between the first electrode 221 and the second electrode 225. A first functional layer 222 may be located between the first electrode 221 and the emission layer 223, and a second functional layer 224 may be located between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to some embodiments, the first electrode 221 may further include a layer formed of ITO, IZO, ZnO, AZO, or In₂O₃ over/under the reflective layer.

The emission layer 223 may include a high molecular weight organic material or a low molecular weight organic material that emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may be formed of a conductive material having a low work function. For example, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the second electrode 225 may further include a layer formed of ITO, IZO, ZnO, AZO, or In₂O₃ on the (semi-)transparent layer including the above material.

FIG. 7B is a cross-sectional view schematically illustrating a light-emitting element of a display apparatus, according to some embodiments of the present disclosure.

Referring to FIG. 7B, a light-emitting element according to some embodiments of the present disclosure may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242 located on the same layer.

According to some embodiments, the first semiconductor layer 231 may include a p-type semiconductor layer. The p-type semiconductor layer may be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with a p-type dopant such as Mg, Zn, Ca, Sr, or Ba.

The second semiconductor layer 232 may include, for example, an n-type semiconductor layer. The n-type semiconductor layer may be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with an n-type dopant such as Si, Ge, or Sn.

The intermediate layer 233 may be an area where electrons and holes recombine to change to a lower energy level and generate light having a corresponding wavelength. The intermediate layer 233 may include a semiconductor material having a composition formula of InₓAl_{y}Ga_{1-x-y}N (0≤x≤1, 0≤y≤1, 0≤x+y≤1), and may have a single or multi-quantum well (MQW) structure. Also, the intermediate layer 233 may have a quantum wire structure or a quantum dot structure.

Although the first semiconductor layer 231 includes a p-type semiconductor layer and the second semiconductor layer 232 includes an n-type semiconductor layer in FIG. 7B, embodiments according to the present disclosure are not limited thereto. According to some embodiments, the first semiconductor layer 231 may include an n-type semiconductor layer, and the second semiconductor layer 232 may include a p-type semiconductor layer.

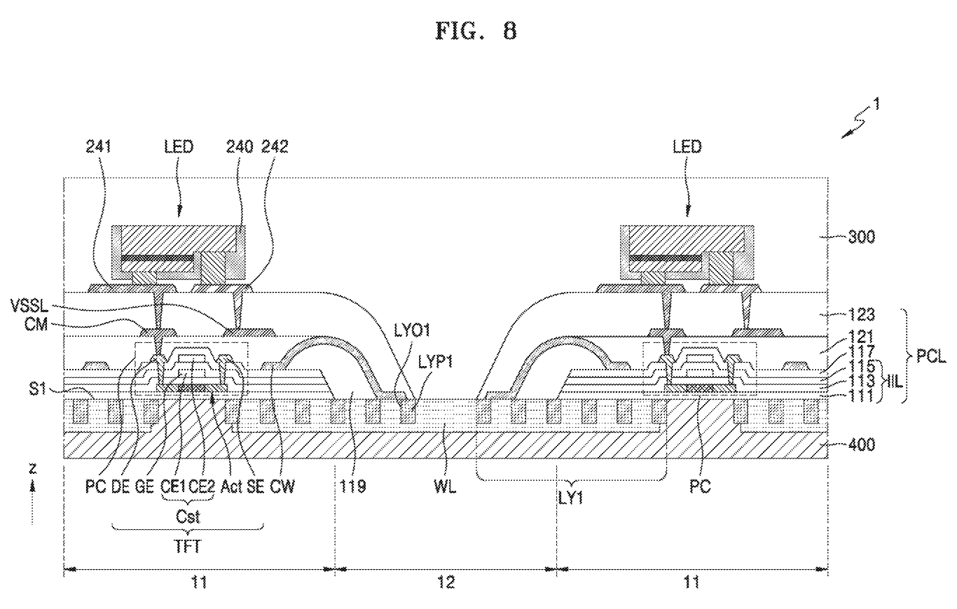

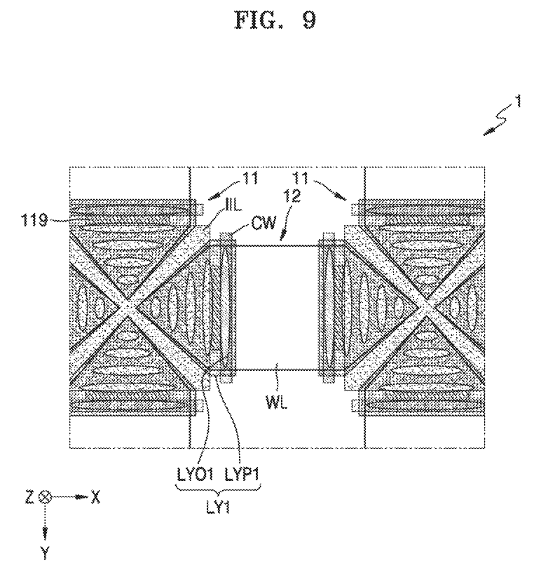

FIG. 8 is a cross-sectional view schematically illustrating a part of the display apparatus 1, according to some embodiments of the present disclosure, and FIG. 9 is a plan view schematically illustrating a part of the display apparatus 1, according to some embodiments of the present disclosure.

In detail, FIG. 9 is a plan view illustrating a part of the display apparatus 1 viewed from the bottom of the display apparatus 1 of FIG. 8 in the third direction (e.g., a z axis direction). In FIG. 9, only an inorganic insulating layer IIL, a first organic insulating layer 121, a contact wiring CW, a first layer LY1, and a connection wiring WL of the display apparatus 1 are illustrated, and the connection wiring WL is transparent.

Referring to FIGS. 8 and 9, the display apparatus 1 may include the pixel circuit layer PCL, the light-emitting element LED, the first layer LY1, the connection wiring WL, a first elastomer layer 400, and a second elastomer layer 300.

The pixel circuit layer PCL may be located in each of a plurality of first island portions 11. The pixel circuit layer PCL may include the inorganic insulating layer IIL and the pixel driving circuit unit PC. The inorganic insulating layer IIL may include the buffer layer 111, a gate insulating layer 113, a first interlayer insulating layer 115, and a second interlayer insulating layer 117. The gate insulating layer 113 may be located on the buffer layer 111, the first interlayer insulating layer 115 may be located on the gate insulating layer 113, and the second interlayer insulating layer 117 may be located on the first interlayer insulating layer 115. The pixel driving circuit unit PC may include a thin-film transistor TFT and the storage capacitor Cst.

The buffer layer 111 may include an inorganic insulating material such as silicon oxide, silicon nitride, or silicon oxynitride.

The thin-film transistor TFT may include a semiconductor layer Act, a gate electrode GE, a source electrode SE, and a drain electrode DE. Although the thin-film transistor TFT is a top gate type transistor in which the gate electrode GE is located on the semiconductor layer Act with the gate insulating layer 113 therebetween in FIG. 8, according to some embodiments, the thin-film transistor TFT may be a bottom gate type transistor.

The semiconductor layer Act may include polysilicon. Alternatively, the semiconductor layer Act may include amorphous silicon, an oxide semiconductor, or an organic semiconductor. The gate electrode GE may include a metal thin film formed of a low-resistance metal material. The gate electrode GE may include a conductive material including molybdenum (Mo), aluminum (Al), copper (Cu), or titanium (Ti), and may have a single or multi-layer structure including the above material. For example, the gate electrode GE may include a metal thin film having a three-layer structure of titanium (Ti)/aluminum (Al)/titanium (Ti).

The gate insulating layer 113 between the semiconductor layer Act and the gate electrode GE may include an inorganic insulating material such as silicon oxide, silicon nitride, silicon oxynitride, aluminum oxide, or titanium oxide. The gate insulating layer 113 may have a single or multi-layer structure including the above material.

The source electrode SE and the drain electrode DE may be located on the same layer, for example, the second interlayer insulating layer 117, and may include the same material. The source electrode SE and the drain electrode DE may include a metal thin film formed of a low-resistance metal material. Each of the source electrode SE and the drain electrode DE may include a conductive material including molybdenum (Mo), aluminum (Al), copper (Cu), or titanium (Ti) and may have a single or multi-layer structure including the above material. For example, each of the source electrode SE and the drain electrode DE may include a metal thin film having a three-layer structure of titanium (Ti)/aluminum (Al)/titanium (Ti), like the gate electrode GE. The second interlayer insulating layer 117 may include an inorganic insulating material such as silicon oxide, nitrogen oxide, silicon oxynitride, aluminum oxide, or titanium oxide, and may have a single or multi-layer structure including the above material.

The storage capacitor Cst may include the first electrode CE1 and the second electrode CE2 overlapping each other with the first interlayer insulating layer 115 therebetween. The storage capacitor Cst may overlap the thin-film transistor TFT. In this regard, in FIG. 8, the gate electrode GE of the thin-film transistor TFT is the first electrode CE1 of the storage capacitor Cst. According to some embodiments, the storage capacitor Cst may not overlap the thin-film transistor TFT. The storage capacitor Cst may be covered by the second interlayer insulating layer 117.

The first interlayer insulating layer 115 may be located between the gate insulating layer 113 and the second interlayer insulating layer 117. The first interlayer insulating layer 115 may include an inorganic insulating material such as silicon oxide, nitrogen oxide, silicon oxynitride, aluminum oxide, or titanium oxide, and may have a single or multi-layer structure including the above material.

The second electrode CE2 of the storage capacitor Cst may include a conductive material and may have a single or multi-layer structure. The second electrode CE2 may include a metal thin film formed of a low resistance metal material. The second electrode CE2 may include a conductive material including molybdenum (Mo), aluminum (Al), copper (Cu), or titanium (Ti), and may have a single or multi-layer structure including the above material. For example, the second electrode CE2 may include a metal thin film having a three-layer structure of titanium (Ti)/aluminum (Al)/titanium (Ti).

The pixel circuit layer PCL may include the first organic insulating layer 121, a second organic insulating layer 123, and a sub-organic insulating layer 119. The first organic insulating layer 121 may be located on the second interlayer insulating layer 117, and the second organic insulating layer 123 may be located on the first organic insulating layer 121. Also, at a boundary portion between the first island portion 11 and the first bridge portion 12, the sub-organic insulating layer 119 may be located between the second interlayer insulating layer 117 and the first organic insulating layer 121. Each of the sub-organic insulating layer 119, the first organic insulating layer 121, and the second organic insulating layer 123 may include an organic insulating material such as polyimide.

The inorganic insulating layer IIL including the buffer layer 111, the gate insulating layer 113, the first interlayer insulating layer 115, and the second interlayer insulating layer 117 may be located only in the first island portion 11 and may not be located in the first bridge portion 12. In other words, a portion of the inorganic insulating layer IIL overlapping the first bridge portion 12 may be removed. In this case, a stepped portion that may occur between the first bridge portion 12 and the first island portion 11 may be filled by the sub-organic insulating layer 119. The second organic insulating layer 123 may extend from the first bridge portion 12 and may be partially located in the first island portion 11.

The pixel circuit layer PCL may have a first pixel surface S1. The first pixel surface S1 may be a surface of the pixel circuit layer PCL facing a direction (e.g., a -z axis direction) away from the light-emitting element LED described below. The first pixel surface S1 may be a bottom surface of the pixel circuit layer PCL (in detail, the buffer layer 111). The first pixel surface S1 may include a flat surface.

The contact wiring CW may be located on the inorganic insulating layer IIL. For example, the contact wiring CW may be located on the second interlayer insulating layer 117. The first organic insulating layer 121 may be located on the contact wiring CW. The contact wiring CW may include at least one of the data line DL and a gate line described with reference to FIGS. 6A to 6C.

A portion of the contact wiring CW located in the first island portion 11 may extend to the first bridge portion 12 and may directly contact the connection wiring WL. The portion of the contact wiring CW extending to the first bridge portion 12 may be located on the sub-organic insulating layer 119. According to some embodiments, an end of the portion of the contact wiring CW extending to the first bridge portion 12 may directly contact the connection wiring WL.

The contact wiring CW may include a conductive material including molybdenum (Mo), aluminum (Al), copper (Cu), or titanium (Ti), and may have a single or multi-layer structure including the above material. For example, the contact wiring CW may include a metal thin film having a three-layer structure of titanium (Ti)/aluminum (Al)/titanium (Ti).

The light-emitting element LED may be located on the pixel circuit layer PCL to be electrically connected to the pixel driving circuit unit PC. A connection electrode CM and the second voltage line VSSL may be located on the first organic insulating layer 121. The connection electrode CM may electrically connect the thin-film transistor TFT to the light-emitting element LED. The second voltage line VSSL may be connected to a common voltage supply wiring and may transmit the second power supply voltage VSS (see FIG. 6A) to the second electrode 238 (see FIG. 7B). Each of the connection electrode CM and the second voltage line VSSL may include a metal thin film formed of a low-resistance metal material. Each of the connection electrode CM and the second voltage line VSSL may include a conductive material including molybdenum (Mo), aluminum (Al), copper (Cu), or titanium (Ti), and may have a single or multi-layer structure including the above material. For example, each of the connection electrode CM and the second voltage line VSSL may include a metal thin film having a three-layer structure of titanium (Ti)/aluminum (Al)/titanium (Ti).

The first electrode pad 241 and the second electrode pad 242 may be located on the second organic insulating layer 123. The first electrode pad 241 may be electrically connected to the thin-film transistor TFT through the connection electrode CM between the first organic insulating layer 121 and the second organic insulating layer 123. The light-emitting element LED on the first electrode pad 241 and the second electrode pad 242 may be the same as the inorganic light-emitting diode 230 described with reference to FIG. 7B. The light-emitting element LED that is the inorganic light-emitting diode 230 (see FIG. 7B) may include the first semiconductor layer 231 (see FIG. 7B), the second semiconductor layer 232 (see FIG. 7B), the intermediate layer 233 (see FIG. 7B) between the first semiconductor layer 231 (see FIG. 7B) and the second semiconductor layer 232 (see FIG. 7B), the first electrode 235 (see FIG. 7B) electrically connected to the first semiconductor layer 231 (see FIG. 7B), and the second electrode 238 (see FIG. 7B) electrically connected to the second semiconductor layer 232 (see FIG. 7B). The light-emitting element LED may be covered by a protective layer 240. The protective layer 240 may include an organic insulating material such as polyimide.

The first layer LY1 may include a first layer portion LYP1 and a first layer opening LYO1. The first layer portion LYP1 may be located on the pixel circuit layer PCL. In detail, the first layer portion LYP1 may be located on the first pixel surface S1, which is a bottom surface of the pixel circuit layer PCL. In this structure, the pixel circuit layer PCL may be located between the light-emitting element LED and the first layer LY1. The first layer opening LYO1 may be located in the first layer portion LYP1. The first layer opening LYO1 may pass through the first layer portion LYP1 along a thickness direction of the first layer portion LYP1.

As shown in FIG. 9, the first layer LY1 may overlap any one of a plurality of first island portions 11 and any one of a plurality of first bridge portions 12. In a plan view, the first layer LY1 may overlap the inorganic insulating layer IIL. For example, the number of first layers LY1 may correspond to the number of contact wirings CW. Two first layers LY1 located adjacent to each other may be spaced apart in the first island portion 11 and/or the first bridge portion 12.

The first layer portion LYP1 may include a material having a high adhesive force to the pixel circuit layer PCL. For example, the first layer portion LYP1 may include a photoresist material, and the first layer opening LYO1 may be formed by using a photolithography process. For example, the first layer portion LYP1 may include a SU8 material. For example, the first layer portion LYP1 may include at least one material selected from among novolac-based resin, polyvinylphenol (PVP), acrylate, norbornene polymer, polytetrafluoroethylene (PTFE), silsesquioxane polymer, polymethylmethacrylate (PMMA), terpolymer, poly(1-butene sulfone) (PBS), novolac-based positive electron resist (NPR), poly(methyl-a-chloroacrylate-co-a-methyl styrene, poly(glycidyl methacrylate-co-ethyl acrylate), polychloromethylstyrene (PCMS), and mixtures thereof.

The connection wiring WL may be located in each of a plurality of first bridge portions 12. The connection wiring WL may be located on the pixel circuit layer PCL. In detail, the connection wiring WL may be located on the first pixel surface S1, which is a bottom surface of the pixel circuit layer PCL. At least a part of the connection wiring WL may be accommodated in the first layer opening LYO1. A thickness of the connection wiring WL may be greater than a thickness of the first layer LY1. The connection wiring WL may cover at least a part of the first layer LY1. The connection wiring WL may include a material having both excellent elasticity and electrical properties. For example, the connection wiring WL may include a liquid metal. For example, the connection wiring WL may include a metal nanostructure and an elastomer. For example, the connection wiring WL may include a conductive composite material including an elastomer.

The contact wiring CW may electrically connect the pixel driving circuit unit PC to the connection wiring WL. One side of the contact wiring CW may contact the connection wiring WL, and the other side of the contact wiring CW may be located on the inorganic insulating layer IIL and may be electrically connected to the pixel driving circuit unit PC. In detail, one side of the contact wiring CW may contact the connection wiring WL accommodated in the first layer opening LYO1.

In this structure, the first layer LY1 may perform an anchor function between the pixel circuit layer PCL and the connection wiring WL. As a part of the connection wiring WL is accommodated in the first layer opening LYO1, a phenomenon where the connection wiring WL slips from the pixel circuit layer PCL during stretching of the display apparatus 1 may be relatively reduced. Accordingly, an adhesive force between the connection wiring WL and the pixel circuit layer PCL may be relatively improved.

As the first layer LY1 is located in the first island portion 11, a modulus of the first island portion 11 may increase. During stretching of the display apparatus 1, stress applied to a portion of the connection wiring WL not overlapping the first layer LY1 may increase and stress applied to the first island portion 11 may decrease. Accordingly, the durability of the first island portion 11 may be relatively improved.

A modulus of the first layer LY1 may be higher than a modulus of the connection wiring WL, and may be lower than a modulus of the inorganic insulating layer IIL. As the first layer LY1 is located between the inorganic insulating layer IIL and the connection wiring WL, a modulus difference between the inorganic insulating layer IIL and the connection wiring WL may be relatively reduced. Accordingly, stress applied to the first island portion 11 may decrease, and the durability of the first island portion 11 may be relatively improved.

The first elastomer layer 400 may be located on the pixel circuit layer PCL to cover the first layer LY1 and the connection wiring WL. In detail, the first elastomer layer 400 may be located on the first pixel surface S1, which is a bottom surface of the pixel circuit layer PCL. The first elastomer layer 400 may absorb stress that may occur during stretching of the display apparatus 1. A side surface of the connection wiring WL and a bottom surface of the connection wiring WL may be surrounded by the first elastomer layer 400. As the connection wiring WL is embedded in the first elastomer layer 400, stress that may be concentrated on the connection wiring WL during stretching of the display apparatus 1 may be absorbed by the first elastomer layer 400.

The first elastomer layer 400 may include an elastomer. For example, the first elastomer layer 400 may include at least one of thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomer, ethylene-vinyl acetate, polydimethylsiloxane (PDMS), and ecoflex.

Also, because the first bridge portion 12 of the display apparatus 1 may be deformed a lot, the inorganic insulating layer IIL may not be located in the first bridge portion 12, and organic insulating layers may be located in the first bridge portion 12. For example, the sub-organic insulating layer 119, the first organic insulating layer 121, and the second organic insulating layer 123 located in the first island portion 11 may extend and be located in the first bridge portion 12.

The second elastomer layer 300 may be located on the light-emitting element LED and the connection wiring WL. The second elastomer layer 300 may cover the light-emitting element LED and the connection wiring WL, and may absorb stress that may be transmitted to the light-emitting element LED and the connection wiring WL. According to some embodiments, the second elastomer layer 300 may include the same material as that of the first elastomer layer 400. However, embodiments according to the present disclosure are not limited thereto, and according to some embodiments, the second elastomer layer 300 may include a material different from that of the first elastomer layer 400.

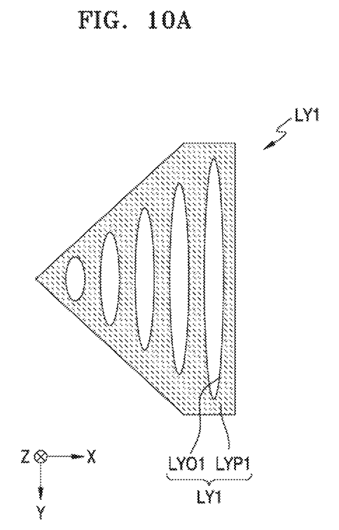

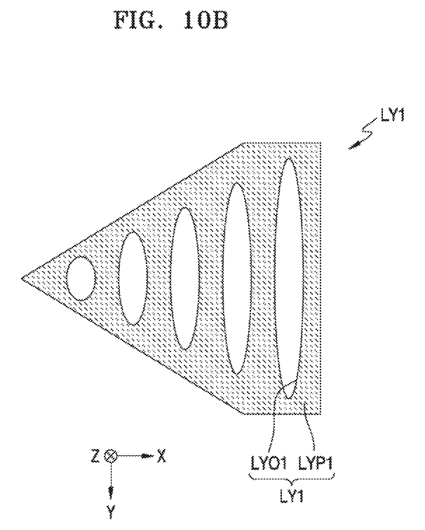

FIGS. 10A and 10B are plan views schematically illustrating the first layer LY1, according to some embodiments of the present disclosure.

In detail, FIG. 10A is a plan view illustrating the first layer LY1 before the display apparatus 1 (see FIG. 1) is stretched. FIG. 10B is a plan view illustrating the first layer LY1 after the display apparatus 1 (see FIG. 1) is stretched. FIGS. 10A and 10B illustrate the first layer LY1 in contact with a stretching wiring connecting two first island portions 11 located adjacent to each other along the first direction (e.g., the x direction and/or the -x direction).

Referring to FIGS. 8 to 10B, the first layer LY1 may include the first layer portion LYP1 and the first layer opening LYO1.

As shown in FIG. 10A, before the display apparatus 1 is stretched, in a plan view, a shape of the first layer opening LYO1 may be an elliptical shape. In detail, a planar shape of the first layer opening LYO1 may be an elliptical shape having a short axis extending in the first direction (e.g., the x direction and/or the -x direction) and a long axis extending in the second direction (e.g., the y direction and/or the -y direction).

As shown in FIG. 10B, after the display apparatus 1 is stretched in the first direction (e.g., the x direction and/or the -x direction), a length of the long axis of the elliptical shape of the first layer opening LYO1 may decrease and a length of the short axis may increase. However, the short axis of the elliptical shape of the first layer opening LYO1 may be maintained to extend in the first direction (e.g., the x direction and/or the -x direction) and the long axis may be maintained to extend in the second direction (e.g., the y direction and/or the -y direction). Alternatively, a planar shape of the first layer opening LYO1 may be a circular shape.

In this structure, even when the display apparatus 1 is stretched in the first direction (e.g., the x direction and/or the -x direction), a phenomenon where a length of the first layer opening LYO1 in the second direction (e.g., the y direction and/or the -y direction) is excessively reduced may be prevented or reduced. Accordingly, while the display apparatus 1 is stretched in the first direction (e.g., the x direction and/or the -x direction), the first layer LY1 may efficiently fix the pixel circuit layer PCL and the connection wiring.

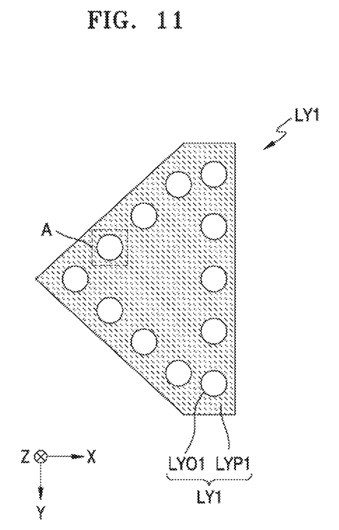

FIG. 11 is a plan view schematically illustrating the first layer LY1, according to some embodiments of the present disclosure.

Referring to FIGS. 10A and 11, a plurality of first layer openings LYO1 may be provided.

As shown in FIG. 10A, the plurality of first layer openings LYO1 may be spaced apart from each other along the first direction (e.g., the x direction and/or the -x direction) in which the first layer portion LYP1 is stretched. For example, five first layer openings LYO1 may be arranged along the first direction (e.g., the x direction and/or the -x direction). As shown in FIG. 11, the plurality of first layer openings LYO1 may be spaced apart from each other along a circumference of the first layer portion LYP1. For example, 12 first layer openings LYO1 may be arranged along the circumference of the first layer portion LYP1. However, this is only an example, and the arrangement and number of the plurality of first layer openings LYO1 are not limited thereto, and may be designed in various ways by considering requirements.

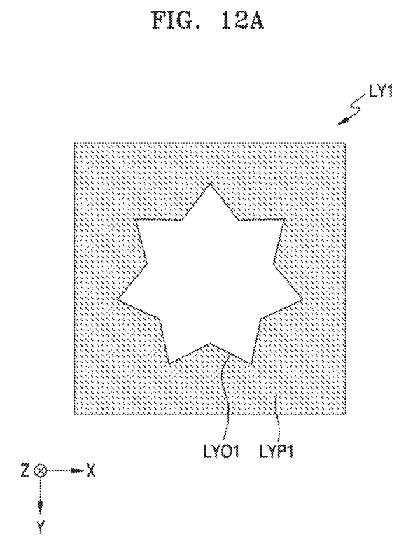

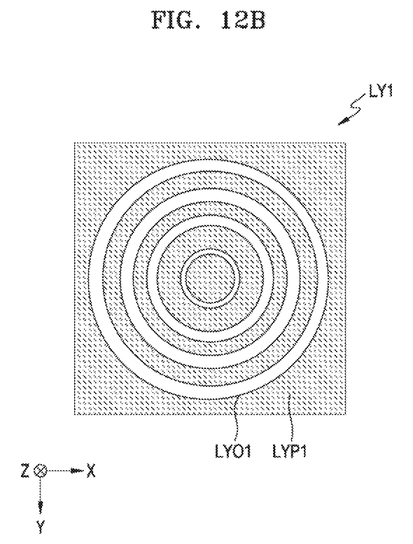

FIGS. 12A and 12B are plan views schematically illustrating the first layer LY1, according to some embodiments of the present disclosure.

In detail, FIGS. 12A and 12B are enlarged views illustrating a portion A of the first layer LY1 of FIG. 11.

Referring to FIGS. 11 to 12B, the first layer opening LYO1 may have any of various shapes.

For example, as shown in FIG. 12A, a planar shape of the first layer opening LYO1 may be a star shape. The planar shape of the first layer opening LYO1 may include a plurality of pointed vertices. For example, an angle between edges in the planar shape of the first layer opening LYO1 may include an obtuse angle and an acute angle. In this structure, due to the angular planar shape of the first layer opening LYO1, an adhesive force between the connection wiring WL (see FIG. 8) and the pixel circuit layer PCL (see FIG. 8) may be relatively improved.

For example, as shown in FIG. 12B, a planar shape of the first layer opening LYO1 may be a concentric circular shape. In this structure, a contact area between the first layer portion LYP1 and the connection wiring WL (see FIG. 8) may increase. Accordingly, an adhesive force between the connection wiring WL (see FIG. 8) and the pixel circuit layer PCL (see FIG. 8) may be relatively improved.

However, this is only an example, and a shape of the first layer opening LYO1 is not limited thereto. For example, as shown in FIG. 11, a planar shape of the first layer opening LYO1 may be a circular shape. For example, as shown in FIG. 11, shapes of a plurality of first layer openings LYO1 may be different from each other.

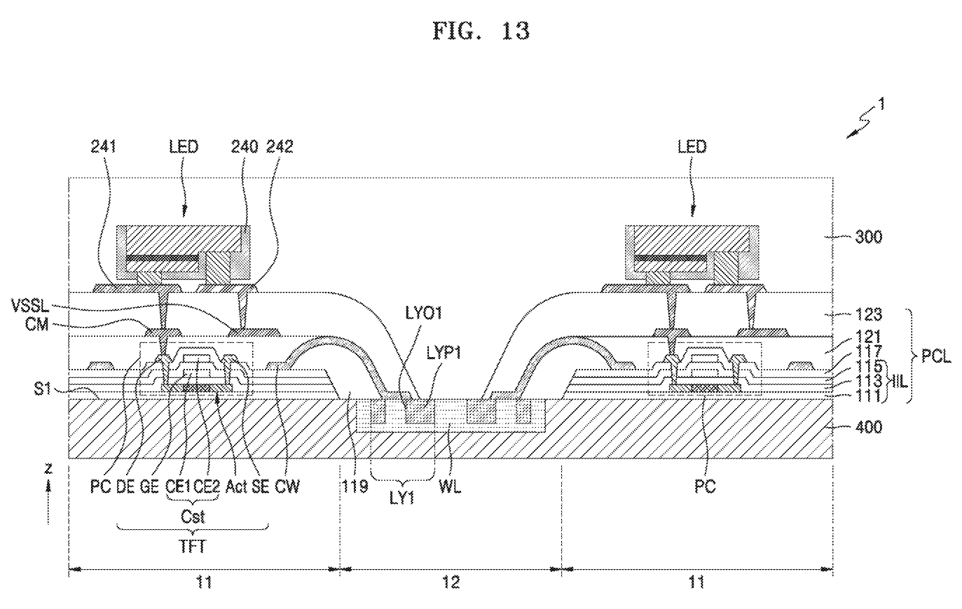

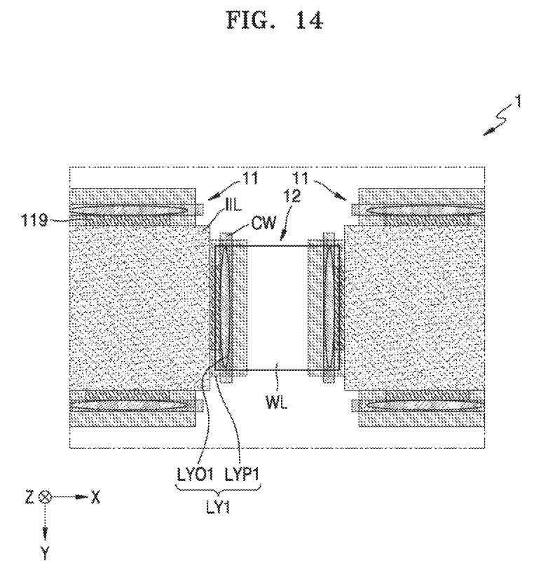

FIG. 13 is a cross-sectional view schematically illustrating a part of the display apparatus 1, according to some embodiments of the present disclosure, and FIG. 14 is a plan view schematically illustrating a part of the display apparatus 1, according to some embodiments of the present disclosure.

In detail, FIG. 14 is a plan view illustrating a part of the display apparatus 1 viewed from the bottom of the display apparatus 1 of FIG. 13 in the third direction (e.g., the z axis direction). In FIG. 14, only the inorganic insulating layer IIL, the first organic insulating layer 121, the contact wiring CW, the first layer LY1, and the connection wiring WL of the display apparatus 1 are illustrated, and the connection wiring WL is transparent.

In FIGS. 13 and 14, the same members as those in FIGS. 8 and 9 are denoted by the same reference numerals, and thus a repeated description thereof will be omitted.

Referring to FIGS. 13 and 14, the display apparatus 1 may include the pixel circuit layer PCL, the light-emitting element LED, the first layer LY1, the connection wiring WL, the first elastomer layer 400, and the second elastomer layer 300.

The pixel circuit layer PCL may be located in each of a plurality of first island portions 11. The pixel circuit layer PCL may include the inorganic insulating layer IIL and the pixel driving circuit unit PC. The inorganic insulating layer IIL may include the buffer layer 111, the gate insulating layer 113, the first interlayer insulating layer 115, and the second interlayer insulating layer 117. The pixel driving circuit unit PC may include the thin-film transistor TFT and the storage capacitor Cst. The thin-film transistor TFT may include the semiconductor layer Act, the gate electrode GE, the source electrode SE, and the drain electrode DE.

The contact wiring CW may be located on the inorganic insulating layer IIL. A portion of the contact wiring CW located in the first island portion 11 may extend to the first bridge portion 12 and may directly contact the connection wiring WL. The light-emitting element LED may be located on the pixel circuit layer PCL to be electrically connected to the pixel driving circuit unit PC.

The connection electrode CM and the second voltage line VSSL may be located on the first organic insulating layer 121. The connection electrode CM may electrically connect the thin-film transistor TFT to the light-emitting element LED. The second voltage line VSLL may be connected to a common voltage supply wiring and may transmit the second power supply voltage VSS (see FIG. 6A) to the second electrode 238 (see FIG. 7B).

The first electrode pad 241 and the second electrode pad 242 may be located on the second organic insulating layer 123. The first electrode pad 241 may be electrically connected to the thin-film transistor TFT through the connection electrode CM between the first organic insulating layer 121 and the second organic insulating layer 123. The light-emitting element LED on the first electrode pad 241 and the second electrode pad 242 may be the same as the inorganic light-emitting diode 230 described with reference to FIG. 7B. The light-emitting element LED may be covered by the protective layer 240.

The first layer LY1 may include the first portion LYP1 and the first layer opening LYO1. The first layer portion LYP1 may be located on the pixel circuit layer PCL. In detail, the first layer portion LYP1 may be located on the first pixel surface S1, which is a bottom surface of the pixel circuit layer PCL. In this structure, the pixel circuit layer PCL may be located between the light-emitting element LED and the first layer LY1. The first layer opening LYO1 may be located in the first layer portion LYP1. The first layer opening LYO1 may pass through the first layer portion LYP1 along a thickness direction of the first layer portion LYP1.

As shown in FIG. 13, the first layer LY1 may overlap any one of a plurality of first bridge portions 12. In a plan view, the first layer LY1 may be spaced apart from the inorganic insulating layer IIL. In a plan view, the first layer LY1 may be spaced apart from a plurality of first island portions 11. The first layer portion LYP1 may include a material having a high adhesive force to the pixel circuit layer PCL.

For example, the connection wiring WL may be located in each of a plurality of first bridge portions 12. The connection wiring WL may be located on the pixel circuit layer PCL. In detail, the connection wiring WL may be located on the first pixel surface S1, which is a bottom surface of the pixel circuit layer PCL. At least a part of the connection wiring WL may be accommodated in the first layer opening LYO1. The connection wiring WL may include a material having both excellent elasticity and electrical properties.

The contact wiring CW may electrically connect the pixel driving circuit unit PC to the connection wiring WL. One side of the contact wiring CW may contact the connection wiring WL, and the other side of the contact wiring CW may be located on the inorganic insulating layer IIL and may be electrically connected to the pixel driving circuit unit PC. In detail, one side of the contact wiring CW may contact the connection wiring WL accommodated in the first layer opening LYO1.

The first elastomer layer 400 may be located on the pixel circuit layer PCL to cover the first layer LY1 and the connection wiring WL. The second elastomer layer 300 may be located on the light-emitting element LED and the connection wiring WL.

The display apparatus 1 according to the above embodiments may be used in various electronic devices capable of providing images. The term “electronic device” refers to a device having a function capable of providing a certain image by using electricity.

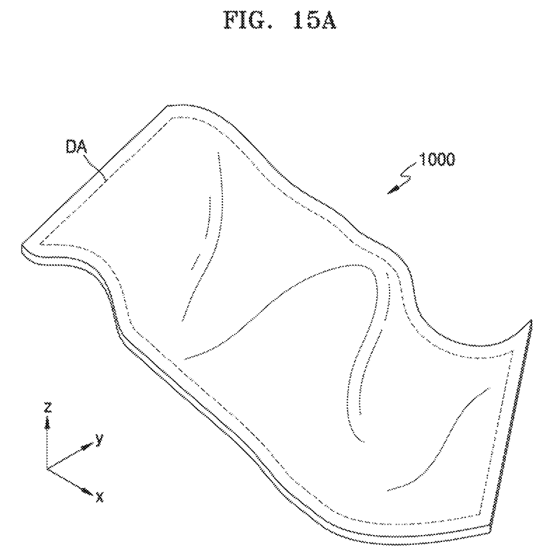

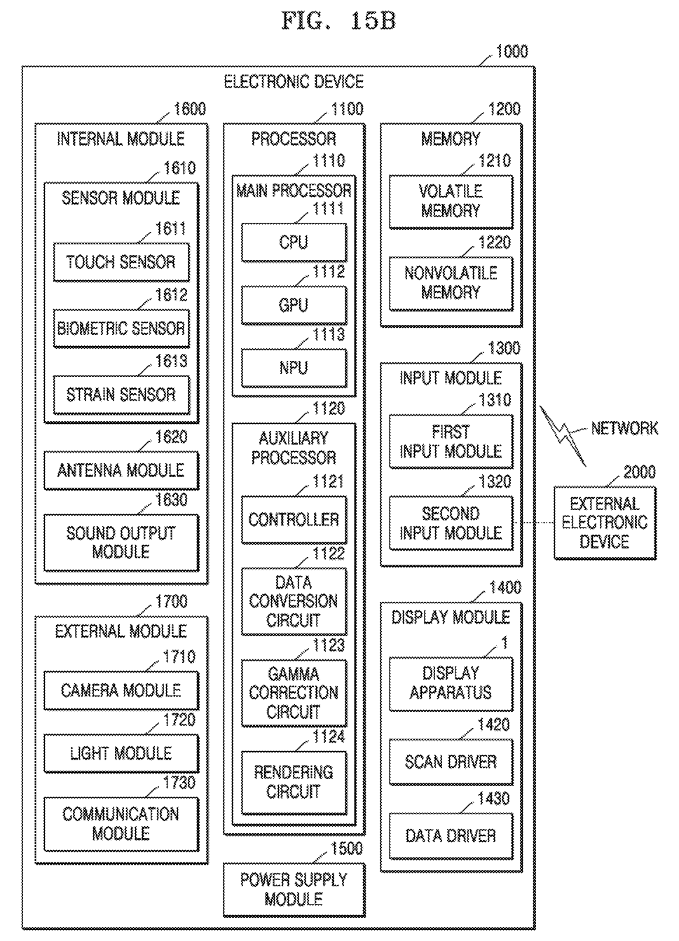

FIG. 15A is a perspective view schematically illustrating an electronic device 1000 including a display apparatus, according to some embodiments of the present disclosure. FIG. 15B is a block diagram schematically illustrating the electronic device 1000 including the display apparatus 1, according to some embodiments of the present disclosure.

Referring to FIG. 15A, the electronic device 1000 may be freely deformed three-dimensionally and may provide a three-dimensional image surface through the display area DA. An operation in which the electronic device 1000 is freely deformed three-dimensionally is distinguished from an operation of an electronic device having a rollable display apparatus, such as an operation in which a part of a display area that was rolled up is visible to a user and then another part of the rolled display area is unfolded, thereby making the entire display area visible to the user (or an operation in which the entire display area that was unfolded is visible to the user and then the display area is rolled up, thereby making only a part of the display area visible to the user). The electronic device 1000 according to embodiments of the present disclosure may be deformed so that the area of the display area DA is increased and then reduced again while the electronic device 1000 is deformed in the x direction, the y direction, and/or the z direction.

Referring to FIG. 15B, the electronic device 1000 may include a processor 1100, a memory 1200, an input module 1300, a display module 1400, a power supply module 1500, an internal module 1600, and an external module 1700. According to some embodiments, in the electronic device 1000, at least one of the above components may be omitted or one or more other components may be added. According to some embodiments, some of the above components (e.g., the internal module 1600) may be integrated into another component (e.g., the display module 1400).

The processor 1100 may control at least one other component (e.g., hardware or software component) of the electronic device 1000 connected to the processor 1100 by executing software and may perform various data processing or calculation. According to some embodiments, as at least part of data processing or calculation, the processor 1100 may store a command or data received from another component (e.g., the input module 1300, a sensor module 1610, or a communication module 1730) in a volatile memory 1210, may process the command or the data stored in the volatile memory 1210, and may store result data in a nonvolatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized in processing an artificial intelligence (AI) model, and the AI model may be generated through machine learning. The AI model may include a plurality of artificial neural network layers. The artificial neural network may be, but is not limited to, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof. The AI model may include a software structure, in addition or alternatively, to a hardware structure. Among the above processing units and processors, at least two may be integrated into one unit (e.g., a single chip) or each may be implemented as an independent unit (e.g., a plurality of chips).

The auxiliary processor 1120 may include a controller 1121. The controller 1121 may include an interface conversion circuit and a timing control circuit. The controller 1121 receives an image signal from the main processor 1110, converts a data format of the image signal to meet the interface specification with the display module 1400, and outputs image data. The controller 1121 may output various control signals necessary for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, and may compensate for the image data so that an image is displayed at a desired luminance according to characteristics of the electronic device 1000 or a user’s settings, or may convert the image data to relatively reduce power consumption or compensate for an afterimage. The gamma correction circuit 1123 may convert image data or a gamma reference voltage so that an image displayed on the electronic device 1000 has desired gamma characteristics. The rendering circuit 1124 may receive image data from the controller 1121, and may render the image data by considering a pixel arrangement of the display apparatus 1 applied to the electronic device 1000. At least one of the data conversion circuit 1122, the gamma correction circuit 1123, and the rendering circuit 1124 may be integrated into another component (e.g., the main processor 1110 or the controller 1121). According to some embodiments, the auxiliary processor 1120 may be integrated into a data driver 1430.

The memory 1200 may store various data used by at least one component (e.g., the processor 1100 or the sensor module 1610) of the electronic device 1000, and input data or output data for commands related to the various data. The memory 1200 may include at least one of the voltage memory 1210 and the nonvolatile memory 1220.

The input module 1300 may receive a command or data to be used in a component (e.g., the processor 1100, the sensor module 1610, or a sound output module 1630) of the electronic device 1000 from the outside of the electronic device 1000 (e.g., the user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input means or a touch input means such as a button, a dome switch, a jog wheel, or a jog switch located on a rear surface or a side surface of the electronic device 1000. The touch input means may include a touchscreen layer of the display apparatus 1.

The second input module 1320 may be connected to various types of external electronic devices 2000 connected to the electronic device 1000 by wire or wirelessly. According to some embodiments, the second input module 1320 may include a high-definition multimedia interface (HDMI), a universal serial bus (USB) interface, an SD card interface, or an audio interface. The second input module 1320 may include a connector for physically connecting the electronic device 1000 to the external electronic device 2000, for example, an HDMI connector, a USB connector, an SD card connector, or an audio connector (e.g., a headphone connector). In response to the external electronic device 2000 being connected to the second input module 1320, the electronic device 1000 may perform appropriate control related to the connected external electronic device 2000.

The display module 1400 visually provides information to the user. The display module 1400 may include the display apparatus 1, a scan driver 1420, and the data driver 1430.

The display apparatus 1 displays (outputs) information processed by the electronic device 1000. The display apparatus 1 may display execution screen information of an application driven by the electronic device 1000 or user interface (UI) or graphical user interface (GUI) information according to the execution screen information.

The scan driver 1420 may be mounted as a driving chip on the display apparatus 1. Alternatively, the scan driver 1420 may be directly formed on the display apparatus 1. For example, the scan driver 1420 may include an amorphous silicon TFT gate driver circuit (ASG), a low-temperature polycrystalline silicon (LTPS) TFT gate driver circuit, or an oxide semiconductor TFT gate driver circuit (OSG) built in the display apparatus 1. The scan driver 1420 receives a control signal from the controller 1121, and outputs scan signals to the display apparatus 1 in response to the control signal.

The display apparatus 1 may further include an emission control driver. The emission control driver outputs an emission control signal to the display apparatus 1 in response to a control signal received from the controller 1121. The emission control driver may be formed separately from the scan driver 1420 or may be integrated into the scan driver 1420.

The data driver 1430 receives a control signal from the controller 1121, converts image data into a data voltage that is an analog voltage in response to the control signal, and then outputs data voltages to the display apparatus 1.

The data driver 1430 may be integrated with some components of the auxiliary processor 1120. For example, the data driver 1430 may be provided as a timing controller embedded driver IC including the controller 1121.

The power supply module 1500 supplies power to components of the electronic device 1000. The power supply module 1500 may include a battery that charges a power supply voltage. Also, the power supply module 1500 may include a connection port, and the connection port may be included in the second input module 1320 to which an external charger for supplying power is connected to charge the battery. Alternatively, the power supply module 1500 may include a wireless power transmission/reception member to charge the battery in a wireless manner. The wireless power transmission/reception member may include a plurality of antenna radiators in the form of coils. The power supply module 1500 may include a power management integrated circuit (PMIC). The PMIC supplies optimized power to each of the components of the electronic device 1000.

The electronic device 1000 may further include the internal module 1600 and the external module 1700. The internal module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display apparatus 1 and a touch sensor driver. The sensor module 1610 may detect an input by the user’s body part or an input by a pen, and may generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input by the user’s body part (e.g., finger) or an input by a pen. The touch sensor 1611 may generate a capacitance change amount, a pressure change amount, or an electromagnetic change amount due to an input as a data value.

The biometric sensor 1512 may generate a data value for recognizing a user’s body part (e.g., fingerprint, iris, or face) or a data value corresponding to body information (e.g., blood pressure, moisture, heart rate, or body composition). The biometric sensor 1512 may use an optical method, an ultrasonic method, or a capacitive method.

The strain sensor 1613 may include a layer, a pattern, or wirings whose measurable physical quantity varies according to stretching of the display apparatus 1. For example, the strain sensor 1613 may include wirings whose resistance and/or capacitance is changed by stretching of the display apparatus 1. According to some embodiments, the strain sensor 1613 may include an optical layer or an optical pattern whose transmittance and/or reflectance is changed by stretching of the display apparatus 1.

The electronic device 1000 may relatively improve the quality of an image displayed on the display apparatus 1 or control the display apparatus 1 based on a change in a physical quantity according to stretching of the display apparatus 1 measured by the strain sensor 1613. A control operation of the display apparatus 1 may include, for example, an operation of displaying an operation image for protecting the display apparatus 1, blocking a voltage for driving the display apparatus 1, or stopping a stretching operation of the display apparatus 1.

According to some embodiments, at least one of the fingerprint sensor 1611, the input sensor 1612, the digitizer 1613, and the strain sensor 1613 may be embedded in the display apparatus 1. For example, at least one of the touch sensor 1611, the biometric sensor 1612, and the strain sensor 1613 may be formed through a continuous process with a process of forming a pixel driving circuit unit and/or a light-emitting element of the display apparatus 1. Accordingly, the display apparatus 1 may function as one of the input modules 1300 that provide an input interface between the electronic device 1000 and the user and may also function as one of the display modules 1400 that provide an output interface between the electronic device 1000 and the user.

According to some embodiments, at least two of the touch sensor 1611, the biometric sensor 1612, and the strain sensor 1613 may be integrated into one sensing panel through the same process. According to some embodiments, the sensing panel may be located between the display apparatus 1 and a window cover located on a front surface of the display apparatus 1, but embodiments according to the present disclosure are not limited thereto.

The antenna module 1620 may include one or more antennas for transmitting a signal or power to the outside or receiving a signal or power from the outside. According to some embodiments, the communication module 1730 may transmit a signal to an external electronic device or may receive a signal from an external electronic device through an antenna suitable for a communication method. An antenna pattern of the antenna module 1620 may be integrated into one component (e.g., the display apparatus 1) of the display module 1400 or the input sensor 1612.

The sound output module 1630 is a device for outputting a sound signal to the outside of the electronic device 1000 and may output sound data received from the communication module 1730 or stored in the memory 1200 in a call signal reception mode, a call mode or a recording mode, a voice recognition mode, or a broadcast reception mode. The sound output module 1630 may output a sound signal related to a function (e.g., a call signal reception sound or a message reception sound) performed in the electronic device 1000. The sound output module 1630 may include a receiver and a speaker. At least one of the receiver and the speaker may be a sound generating device that is attached to a rear surface of the display apparatus 1 and outputs sound by vibrating the display apparatus 1. The sound generating device may be a piezoelectric element or a piezoelectric actuator that contracts or expands according to an electrical signal, or an exciter that generates a magnetic force by using a voice coil and vibrates the display apparatus 1.

The camera module 1710 may capture a still image and a moving image. According to some embodiments, the camera module 1710 may include one or more lenses, an image sensor, or an image signal processor. The camera module 1710 may further include an infrared camera for measuring the presence or absence of the user, a location of the user, and a gaze of the user.

The light module 1720 may output a signal for notifying the occurrence of an event by using light of a light source, or may provide light for obtaining an image. Examples of the event may include message reception, call signal reception, missing call, alarm, schedule notification, email reception, and battery charging capacity information notification. The light module 1720 may include a light-emitting diode or a xenon-lamp. The light module 1720 may emit light of a single color or multiple colors to a front surface or a rear surface of the electronic device 1000. The light module 1720 may interoperate with the camera module 1710 or may independently operate.

The communication module 1730 may support establishing a wired or wireless communication channel between the electronic device 1000 and the external electronic device 2000 and performing communication through the established communication channel. The communication module 1730 may include one or both of a wireless communication module such as a cellular communication module, a short-range wireless communication module, or a global navigation satellite system (GNSS) communication module and a wired communication module such as a local area network (LAN) communication module or a power line communication module. The communication module 1730 may transmit and receive a wireless signal on the Internet by using at least one of wireless LAN (WLAN), wireless-fidelity (Wi-Fi), Wi-Fi direct, and digital living network alliance (DLNA). Also, the communication module 1730 may support short-range communication by using at least one of Bluetooth™, radio frequency identification (RFID), infrared data association (IrDA), ultra-wideband (UWB), ZigBee, near-field communication (NFC), Wi-Fi, Wi-Fi direct, and wireless universal serial bus (USB). The various types of communication modules 1730 described above may be implemented as one chip or may be implemented as separate chips.

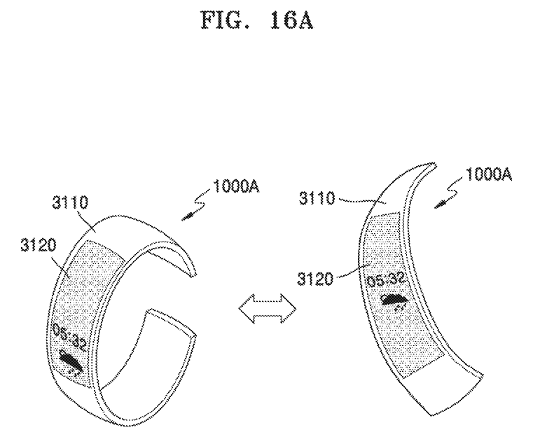

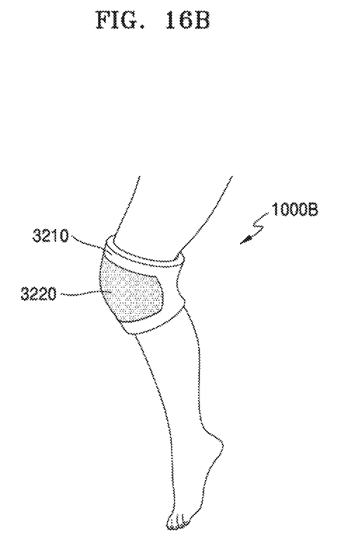

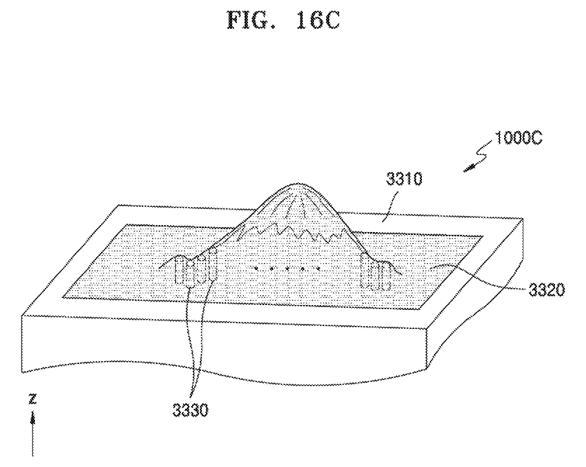

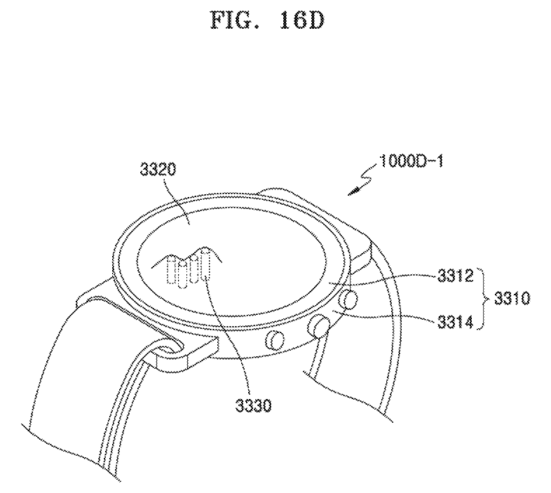

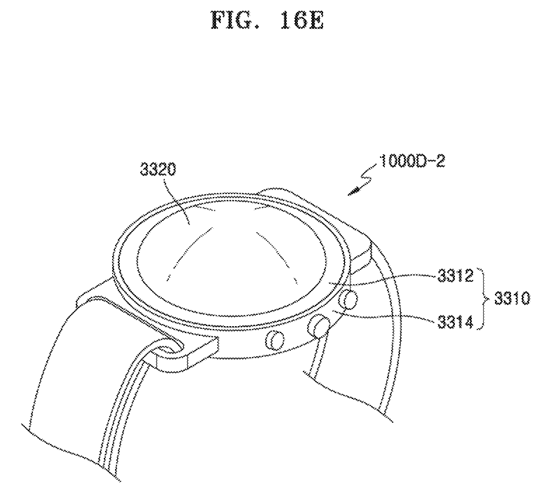

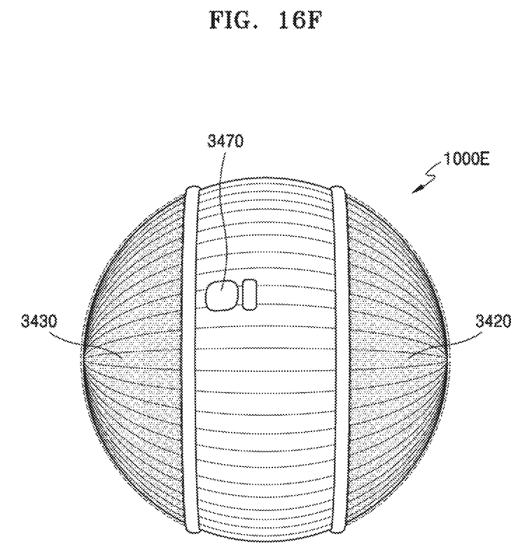

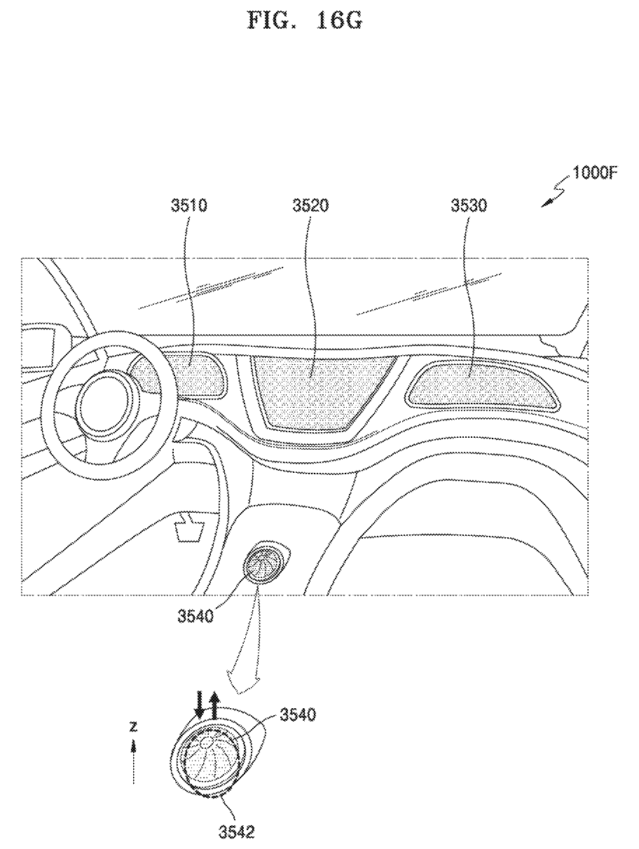

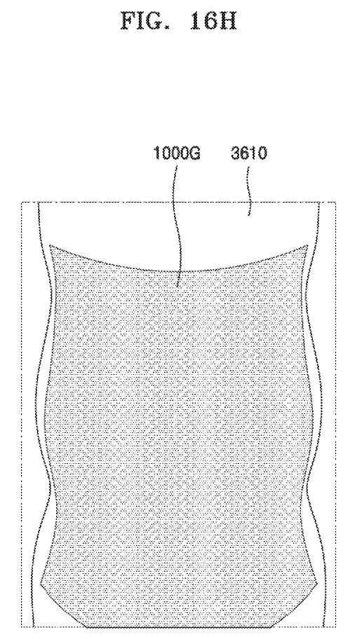

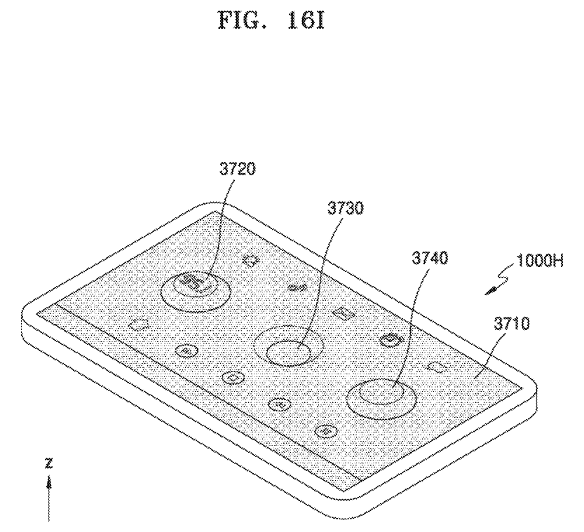

FIGS. 16A to 16I are perspective views schematically illustrating embodiments of an electronic device including a display apparatus, according to some embodiments of the present disclosure.

Referring to FIG. 16A, a display apparatus according to some embodiments of the present disclosure may be used in a wearable electronic device 1000A that may be worn on a user’s body part. The wearable electronic device 1000A may include a body portion 3110 and a display unit 3120 provided on the body portion 3110. A display apparatus according to embodiments of the present disclosure may be used as the display unit 3120 of the wearable electronic device 1000A. As shown in FIG. 16A, the wearable electronic device 1000A may be deformable. According to some embodiments, the wearable electronic device 1000A may be used as a smartwatch or a smartphone according to the user’s selection.

FIG. 16B illustrates a medical electronic device 1000B. According to some embodiments, the medical electronic device 1000B may include a body portion 3210 and a light-emitting unit 3220. A display apparatus according to embodiments of the present disclosure may be used as the light-emitting unit 3220 of the medical electronic device 1000B. The light-emitting unit 3220 may emit light of a certain wavelength band (e.g., infrared light or visible light) to a patient’s body. According to some embodiments, the body portion 3210 may include a stretchable fiber material, and may have a structure that may be worn on a user’s body.

FIG. 16C illustrates an educational electronic device 1000C. According to some embodiments, the educational electronic device may include a display unit 3320 provided in a housing 3310. The display unit 3320 may use a display apparatus according to embodiments of the present disclosure. An image such as a sea with waves, a snow-covered mountain, or a volcano through which lava flows may be provided through the display unit 3320, and in this case, the display unit 3320 may be stretched in a height direction (e.g., the z direction) by reflecting the height of the waves, mountain, or volcano. According to some embodiments, a part of the display unit 3320 may be sequentially changed in height along a direction in which the lava flows to three-dimensionally show the movement of the lava. The educational electronic device 1000C may include a plurality of pins (or stroke units) 3330 located on a rear surface of the display unit 3320 so that the display unit 3320 is stretched in the height direction. As the pins 3330 move along the third direction (e.g., the z direction or the -z direction), an image displayed on the display unit 3320 may be implemented to have a three-dimensional height. Although the educational electronic device 1000C is described with reference to FIG. 16C, its use is not limited as long as certain image information is provided.

FIGS. 16D and 16E illustrate the use of a display apparatus in wearable electronic devices 1000D-1 and 1000D-2 such as smart watches.

According to some embodiments, because a display apparatus corresponding to the display unit 3320 of the electronic device 1000D-1 is three-dimensionally stretchable as shown in FIG. 16D, various haptic information in addition to visual information through an image may be provided to the user. According to some embodiments, the electronic device 1000D-1 may provide haptic information such as Braille display for the visually impaired or tactile stimulation linked to an image by using the plurality of pins (or stroke units) 3330 located under the display unit 3320. The display apparatus corresponding to the display unit 3320 is three-dimensionally stretchable and thus may provide the haptic information. The electronic device 1000D-1 may include the body portion 3310 including a housing 3314 in which the display apparatus for forming the display unit 3320 and the pins (or stroke units) 3330 are accommodated and a frame 3312 that may be coupled to the housing 3314 with the display apparatus therebetween. According to some embodiments, the frame 3312 may be integrally formed with the housing 3314.

The electronic device 1000D-2 of FIG. 16E may include the body portion 3310 and the display unit 3320 that is accommodated in the body portion 3310 and may provide visual information, like in FIG. 16D. According to some embodiments, because the display apparatus corresponding to the display unit 3320 is three-dimensionally stretchable, the display apparatus may include the display unit 3320 having a dome shape. According to some embodiments, the display apparatus may be assembled on a dome-shaped body frame in a process of manufacturing the electronic device 1000D-2, and in this case, the display apparatus is three-dimensionally stretchable, and thus may be assembled while being stretched along a shape of the hemispherical body frame.

FIG. 16F illustrates that an electronic device 1000E includes a robot, according to some embodiments of the present disclosure. The robot may recognize movement or an object by using a camera unit 3470, and may display a certain image to a user through display units 3420 and 3430.

According to some embodiments, because display apparatuses according to some embodiments of the present disclosure may be stretched in various directions as described above, the display apparatuses may be assembled to a body frame having a hemispherical shape, and thus, the robot may include the display units 3420 and 3430 each having a hemispherical shape.

FIG. 16G illustrates a display device 1000F for a vehicle as an electronic device, according to some embodiments of the present disclosure. The display device 1000F for a vehicle may include a cluster 3510, a center information display (CID) 3520, and/or a co-driver display 3530. Because a display apparatus according to some embodiments of the present disclosure may be stretched in various directions, the display apparatus may be used in the cluster 3510, the CID 3520, and/or the co-driver display 3530 regardless of a shape of an internal frame of a vehicle.

Although the cluster 3510, the CID 3520, and/or the co-driver display 3530 are separated from each other in FIG. 16H, embodiments according to the present disclosure are not limited thereto. According to some embodiments, two or more selected from the cluster 3510, the CID 3520, and the co-driver display 3530 may be integrally connected.

According to some embodiments, the display device 1000F for a vehicle may include a button 3540 for displaying a certain image. Referring to an enlarged view of FIG. 16H, the button 3540 having a hemispherical shape may include an object 3542 that provides a feeling of using the button while moving in the z direction or the -z direction, and a display apparatus located on the object 3542. According to some embodiments, when the object 3542 has a three-dimensional rounded surface, the display apparatus may also have a three-dimensional rounded surface.

FIG. 16H illustrates an electronic device 1000G for advertisement or exhibition as an electronic device, according to some embodiments of the present disclosure. According to some embodiments, the electronic device 1000G for advertisement or exhibition may be installed on a fixed structure 3610 such as a wall or a pillar. When the structure 3610 includes an uneven surface as shown in FIG. 16H, the electronic device 1000G for advertisement or exhibition may be arranged along the uneven surface of the structure 3610. According to some embodiments, the electronic device 1000G for advertisement or exhibition may be installed on the structure 3610 by using a heat shrink film or the like.

FIG. 16I illustrates that an electronic device 1000H is a controller, according to some embodiments of the present disclosure. The controller may include an image-type button. For example, a display unit 3710 of the controller may include first to third button areas 3720, 3730, and 3740 protruding in the z direction or protruding in the -z direction (or recessed in the z direction). According to some embodiments, the first and third button areas 3720 and 3740 may protrude in the z direction, and the second button area 3730 may protrude in the -z direction (or be recessed in the z direction).

While aspects of some embodiments of the present disclosure have been particularly shown and described with reference to embodiments thereof, it will be understood by one of ordinary skill in the art that various modifications and equivalent other embodiments made be made from the present disclosure. Accordingly, the true technical scope of the present disclosure is defined by the technical spirit of the appended claims, and their equivalents.

### Description of Some of the Reference Symbols

1: display apparatus

PCL: pixel circuit layer

WL: connection wiring

CW: contact wiring

LY1: first layer

LYP1: first layer portion

LYO1: first layer opening

What is claimed is:

1. A display apparatus comprising:
a plurality of first island portions and a plurality of first bridge portions connecting the plurality of first island portions;
a pixel circuit layer in each of the plurality of first island portions and comprising an inorganic insulating layer and a pixel driving circuit unit;
a light-emitting element on the pixel circuit layer and electrically connected to the pixel driving circuit unit;
a first layer comprising a first layer portion on the pixel circuit layer and a first layer opening passing through the first layer portion;
a connection wiring in each of the plurality of first bridge portions and having at least a part accommodated in the first layer opening; and
a contact wiring electrically connecting the pixel driving circuit unit to the connection wiring.

2. The display apparatus of claim 1, wherein the pixel circuit layer is between the light-emitting element and the first layer.

3. The display apparatus of claim 1, wherein
a first side of the contact wiring contacts the connection wiring, and
a second side of the contact wiring is on the inorganic insulating layer and is electrically connected to the pixel driving circuit unit.

4. The display apparatus of claim 3, wherein the first side of the contact wiring contacts the connection wiring in the first layer opening.

5. The display apparatus of claim 1, wherein, in a plan view, the first layer overlaps any one of the plurality of first island portions and any one of the plurality of first bridge portions.

6. The display apparatus of claim 1, wherein, in a plan view, the first layer is spaced apart from the plurality of first island portions.

7. The display apparatus of claim 1, wherein a thickness of the connection wiring is greater than a thickness of the first layer.

8. The display apparatus of claim 1, wherein, in a plan view, a shape of the first layer opening is an elliptical shape.

9. The display apparatus of claim 1, wherein a plurality of first layer openings are provided.

10. The display apparatus of claim 9, wherein the plurality of first layer openings are arranged along a circumference of the first layer portion.

11. An electronic device comprising a display apparatus that is stretchable,
wherein the display apparatus comprises:
a pixel circuit layer having a first pixel surface and comprising an inorganic insulating layer and a pixel driving circuit unit;
a light-emitting element on the pixel circuit layer and electrically connected to the pixel driving circuit unit;
a first layer comprising a first layer portion on the first pixel surface and a first layer opening passing through the first layer portion;
a connection wiring on the first pixel surface such that at least a part of the connection wiring is accommodated in the first layer opening; and
a contact wiring electrically connecting the pixel driving circuit unit to the connection wiring.

12. The electronic device of claim 11, wherein
a first side of the contact wiring is on the first pixel surface and contacts the connection wiring, and
a second side of the contact wiring is on the inorganic insulating layer and is electrically connected to the pixel driving circuit unit.

13. The electronic device of claim 12, wherein the first side of the contact wiring contacts the connection wiring accommodated in the first layer opening.

14. The electronic device of claim 11, wherein the first pixel surface is a surface of the pixel circuit layer facing a direction away from the light-emitting element.

15. The electronic device of claim 11, wherein a thickness of the connection wiring is greater than a thickness of the first layer.

16. The electronic device of claim 11, wherein, in a plan view, the first layer overlaps the inorganic insulating layer.

17. The electronic device of claim 11, wherein, in a plan view, the first layer is spaced apart from the inorganic insulating layer.

18. The electronic device of claim 11, wherein, in a plan view, a shape of the first layer opening is an elliptical shape.

19. The electronic device of claim 11, wherein a plurality of first layer openings are provided.

20. The electronic device of claim 19, wherein the plurality of first layer openings are arranged along a circumference of the first layer portion.
